(19) United States
(12) Patent Application Publication
(10) Pub. No.: US 2019/0086454 A1
(43) Pub. Date: Mar. 21, 2019

(54) SYSTEMS AND METHODS FOR MANAGING RESOURCE UTILIZATION IMPROVEMENTS

(71) Applicant: ELUTIONS Inc., Tampa, FL (US)

(72) Inventors: Nitin Ranjan, Saint Petersburg, FL (US); David J. Mader, Dousman, WI (US); Christopher M. Voss, Shawano, WI (US); Alain F. Bouvet, Lyon (FR); Elalmis Murat, Saint-Priest (FR)

(73) Assignee: Elutions IP Holdings S.à.r.l., Luxembourg (LU)

(21) Appl. No.: 15/709,353

(22) Filed: Sep. 19, 2017

Related U.S. Application Data
(63) Continuation of application No. 15/708,115, filed on Sep. 18, 2017.

(51) Int. Cl. G01R 21/133; G06Q 10/06; G06Q 50/06

(52) U.S. Cl. CPC G01R 21/133; G06Q 10/06315; G06Q 50/06

(57) ABSTRACT

Systems and methods for managing resource consumption. One or more servers may receive, from a facility, data produced by one or more sensors installed at the facility. The one or more servers may detect an anomaly by comparing the received data with one or more data values describing expected values for the received data and identify a deviation of the received data from the expected values. In response to detecting the anomaly, the one or more servers may generate an event record associated with the anomaly, the event record may comprise an expected cost savings associated with correction of the anomaly and at least one proposed measure expected to correct the anomaly. The event record may be updated to indicate said implementation of the one or more of the at least one proposed measures.

### RELATED APPLICATIONS

This application is a continuation claiming the benefit under 35 U.S.C. § 120 of U.S. application Ser. No. 15/708,115, filed on Sep. 18, 2017, entitled “SYSTEMS AND METHODS FOR MANAGING RESOURCE CONSUMPTION.” U.S. application Ser. No. 15/708,115 was filed on the same day as International Application No. PCT/US17/52092, entitled “SYSTEMS AND METHODS FOR DISPLAYING RESOURCE SAVINGS,” bearing Attorney Docket No. E0533.70001WO00, and International Application No. PCT/US17/52113, entitled “SYSTEMS AND METHODS FOR CONFIGURING DISPLAY LAYOUT,” bearing Attorney Docket No. E0533.70002WO00. Each of these applications is hereby incorporated by reference in its entirety.

### BACKGROUND

Increasingly, both public and private enterprises rely on computer systems to monitor and control resource consumption of various equipment such as heating, ventilation, and air conditioning (HVAC), refrigeration, lighting, and/or mechanical load. These computer systems process vast amounts of data (e.g., sensor data received in real time from individual assets) to identify opportunities for resource conservation. For example, a recommendation may be made to operate an asset in a different manner, so that less energy may be used while maintaining a certain level of service. Such a recommendation may be implemented automatically, or may be reviewed and approved by a human user prior to implementation.

An effective consumption management system may significantly reduce an enterprise's environmental footprint, as well as operating costs.

### SUMMARY

In some embodiments, a consumption management system is provided, comprising: at least one storage medium storing a hierarchical data structure, the hierarchical data structure comprising a first level, a second level, and a third level, the third level being lower than the first level and the second level, wherein: the first level comprises a plurality of nodes corresponding, respectively, to a plurality of locations, the plurality of nodes at the first level comprising a first node; the second level comprises a plurality of nodes corresponding, respectively, to a plurality of load categories, the plurality of nodes at the second level comprising a second node that descends from the first node; the third level comprising a plurality of nodes corresponding, respectively, to a plurality of resource consumption meters, the plurality of nodes at the third level comprising a third node that descends from the second node; and a resource consumption meter corresponding to the third node is located at a location corresponding to the first node, and measures resource consumption of one or more pieces of equipment that fall under a load category corresponding to the second node; and at least one processor programmed to access the hierarchical data structure.

In some embodiments, a method is provided, as performed by the above system.

In some embodiments, at least one computer-readable storage medium is provided, storing executable instructions that, when executed, cause at least one processor to perform the above method.

In some embodiments, a computer-implemented method of managing resource consumption is provided, comprising: receiving from a facility, by one or more servers, data produced by one or more sensors installed at the facility; detecting, by the one or more servers, an anomaly by comparing the received data with one or more data values describing expected values for the received data and identifying a deviation of the received data from the expected values; and in response to detecting the anomaly, calculating, by the one or more servers, an expected cost savings associated with correction of the anomaly, said calculation comprising: determining a usage price of at least one resource associated with the anomaly; determining, based on the received data, an amount of the at least one resource utilized by the facility as a result of the anomaly; and determining the expected cost savings based on the usage price and the amount of the at least one resource utilized by the facility as a result of the anomaly.

In some embodiments, a system is provided, comprising at least one processor and at least one computer-readable storage medium storing executable instructions that, when executed, cause the at least one processor to perform the above method.

In some embodiments, at least one computer-readable storage medium is provided, storing executable instructions that, when executed, cause at least one processor to perform the above method.

In some embodiments, a computer-implemented method of managing resource consumption is provided, comprising: receiving from a facility, by one or more servers, data produced by one or more sensors installed at the facility; detecting, by the one or more servers, an anomaly by comparing the received data with one or more data values describing expected values for the received data and identifying a deviation of the received data from the expected values; in response to detecting the anomaly, generating, by the one or more servers, an event record associated with the anomaly, the event record comprising an expected cost savings associated with correction of the anomaly and at least one proposed measure expected to correct the anomaly; presenting at least a portion of the event record to a user via at least one user interface; receiving user input via the at least one user interface indicating that one or more of the at least one proposed measures have been implemented; and updating the event record to indicate said implementation of the one or more of the at least one proposed measures.

In some embodiments, a system is provided, comprising at least one processor and at least one computer-readable storage medium storing executable instructions that, when executed, cause the at least one processor to perform the above method.

In some embodiments, at least one computer-readable storage medium is provided, storing executable instructions that, when executed, cause at least one processor to perform the above method.

### BRIEF DESCRIPTION OF DRAWINGS

FIG. 1 shows an illustrative consumption management system 100, in accordance with some embodiments.

FIGS. 2A-2B show, respectively, an illustrative virtual meter 210 and an illustrative virtual meter 252, in accordance with some embodiments.

FIGS. 3A-3F show an illustrative object tree 300 for organizing resource consumption data, in accordance with some embodiments.

FIG. 4 shows an illustrative state transition diagram 400 for a consumption management event, in accordance with some embodiments.

FIG. 5 shows an illustrative process 500 for detecting events and calculating cost savings for a consumption management system, in accordance with some embodiments.

FIG. 6A shows an illustrative schedule for a pumping station, in accordance with some embodiments.

FIG. 6B shows illustrative flow rate data for a pumping station from which events may be generated, in accordance with some embodiments.

FIG. 6C shows illustrative event records created for a pumping station comprising resource management recommendations, in accordance with some embodiments.

FIG. 7 shows an illustrative event definition page 700, according to some embodiments.

FIG. 8 shows an illustrative process 800 for detecting events and calculating cost savings for a consumption management system, in accordance with some embodiments.

FIG. 9 shows an illustrative event simulation page 900, according to some embodiments.

FIG. 10 shows, schematically, an illustrative computer 1000 on which any aspect of the present disclosure may be implemented.

### DETAILED DESCRIPTION

The inventors have recognized and appreciated various technical challenges in building a consumption management system.

For instance, the inventors have recognized and appreciated that some consumption management systems are designed to monitor and control specific types of equipment (e.g., HVAC, refrigeration, lighting, mechanical load, etc.). Such a system may be able to handle only a certain type of input data (e.g., operating parameters of HVAC equipment), and it may be impractical to extend such a system to handle another type of input data (e.g., operating parameters of mechanical equipment). As a result, an enterprise that operates different types of equipment may have to use disparate consumption management systems.

The inventors have recognized and appreciated that it may be desirable to provide a more scalable consumption management system. Accordingly, in some embodiments, techniques may be provided for modeling various types of equipment in a unified manner. For instance, techniques may be provided for processing and storing data from multiple, disparate sources in a unified manner. One or more of these techniques may allow a consumption management system to be deployed in any vertical (e.g., telecommunication, cloud computing, retail, public utility, education, hospitality, manufacturing, transportation, etc.) to manage any type of resource consumption (e.g., electricity, gas, water, etc.).

The inventors have further recognized and appreciated that some consumption management systems provide recommendations without quantifying expected benefits. As a result, there may be little guarantee that resource consumption would actually be reduced by implementing a recommendation. Moreover, even if resource consumption would be reduced by implementing a recommendation, there may be no indication of how much reduction could be expected. Without such information, a user may not be able to make an informed decision on whether to implement the recommendation.

Accordingly, in some embodiments, techniques are provided for quantifying expected cost savings associated with a proposed measure to manage consumption. The inventors have recognized and appreciated that it may be efficient to identify opportunities to reduce consumption and simultaneously calculate expected cost savings. For instance, in some embodiments, a rules engine may apply one or more rules to identify opportunities to reduce consumption, and may output proposed measures for reducing consumption, along with estimated cost savings. In this manner, a user may be able to make informed decisions on whether to implement the proposed measures. Furthermore, in some embodiments, actual savings may be determined after one or more proposed measures have been implemented, and may be compared with the estimated savings output by the rules engine. This comparison may be used to adapt one or more rules used by the rules engine (e.g., using one or more machine learning techniques), so that more accurate estimates of savings may be produced in the future.

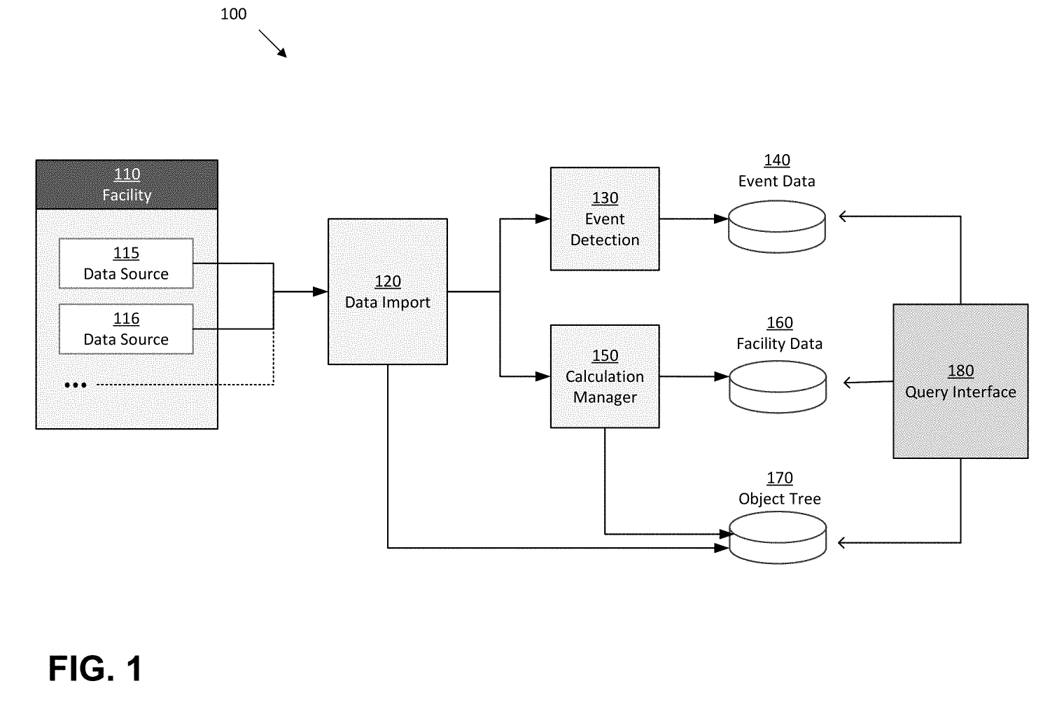

FIG. 1 shows an illustrative consumption management system 100, in accordance with some embodiments. In the example of FIG. 1, the consumption management system 100 imports data from data sources 115, 116, . . . of a facility 110. The consumption management system may check, correct, perform calculations on, and/or otherwise process the imported data to produce structured data that may be readily accessed via a query interface 180, which may include an application programming interface (API) and/or a user interface. For instance, in some embodiments, a query engine may be provided for querying one or more databases in the consumption management system 100.

In some embodiments, the consumption management system 100 may maintain one or more data stores. As an example, the consumption management system 100 may maintain an object tree 170, which may be a hierarchical data structure for organizing data in a logical manner that facilitates rapid retrieval. As another example, the consumption management system 100 may maintain a facility data store 160, which may include data assembled from various data sources, such as data imported from the data sources 115, 116, . . . , and/or one or more quantities derived from the imported data. As yet another example, the consumption management system 100 may maintain an event data store 140, which may indicate, based on the imported data, identified resource consumption recommendations with associated quantified expected benefits. As explained further below, the inventors have recognized and appreciated various benefits provided by maintaining data stores such as the object tree 170, the facility data store 160, and/or the event data store 140. However, it should be appreciated that aspects of the present disclosure are not limited to the use of any particular one of these data stores.

In some embodiments, the consumption management system 100 may be hosted on one or more computing devices that are located remotely from the facility 110. For instance, the consumption management system 100 may receive data from the data sources 115, 116, . . . via one or more networks (e.g., the Internet). In some embodiments, one or more communications to and/or from the consumption management system 100 may be encrypted to protect privacy. For example, a secure tunnel may be established between the consumption management system 100 and a local network at the facility 110 (e.g., using a virtual private network technology). However, it should be appreciated that aspects of the present disclosure are not limited to the use of any secure tunnel. For instance, in some embodiments, one or more components of the consumption management system 100 may be hosted on one or more computing devices on a local network at the facility 110.

In the example of FIG. 1, the facility 110 may be a site operated by an enterprise (e.g., utility company, healthcare organization, university, cloud computing provider, retail chain, etc.), and may include one or more parts of a building, an entire building, and/or a plurality of buildings where one or more pieces of energy consuming equipment may be located. For instance, the facility 110 may include a water treatment plant, a hospital, a university campus, a data center, a grocery store, a factory, a bakery, a farm, etc. The data sources 115, 116, . . . may provide various types of data collected from the facility 110. Such data may be indicative of one or more aspects of operation of the facility 100.

Although not shown in FIG. 1, the consumption management system 100 may, in some embodiments, receive data from one or more facilities other than the facility 110. Each such facility may be operated by a same enterprise or different enterprises, and may include any suitable combination of one or more data sources.

In some embodiments, a data source may include a sensor installed at the facility 110. The sensor may obtain data from an environment at the facility 110, and may produce data indicative of that environment. Examples of sensors include, but are not limited to, an electrical load sensor, temperature sensor, motion sensor, air flow meter, chemical detector (e.g., ozone monitor, carbon monoxide detector, etc.), current detector, voltage detector, hygrometer, barometer, etc., and suitable combinations thereof. It will be appreciated that such a sensor may be coupled to equipment having one or more properties that are sensed by the sensor. For instance, an electrical load sensor may be coupled to an electrical meter, and may read an electrical load present within the meter and produce data indicative of said load.

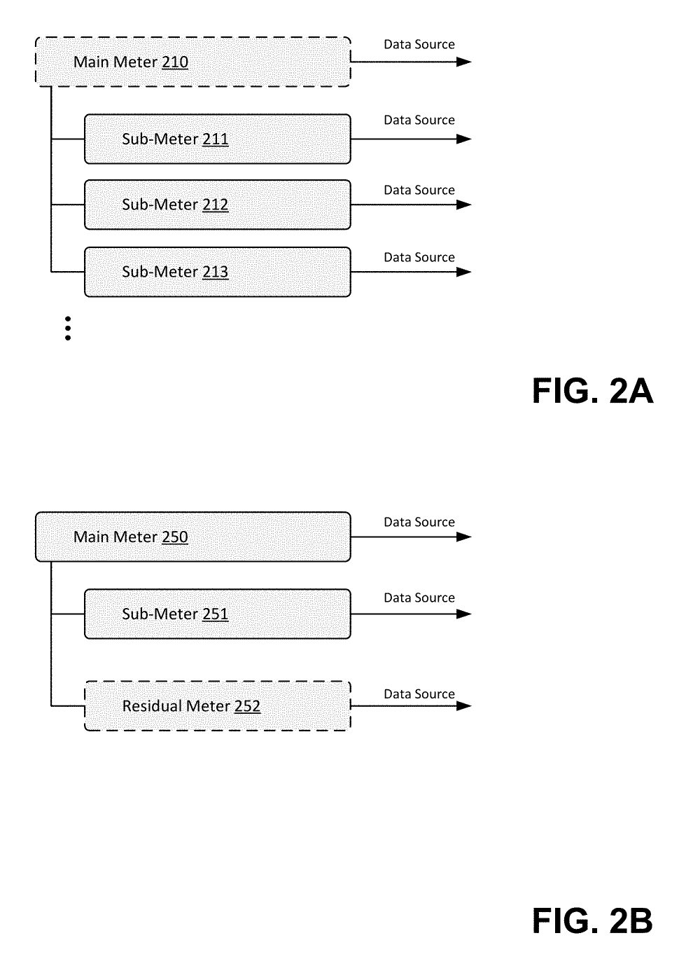

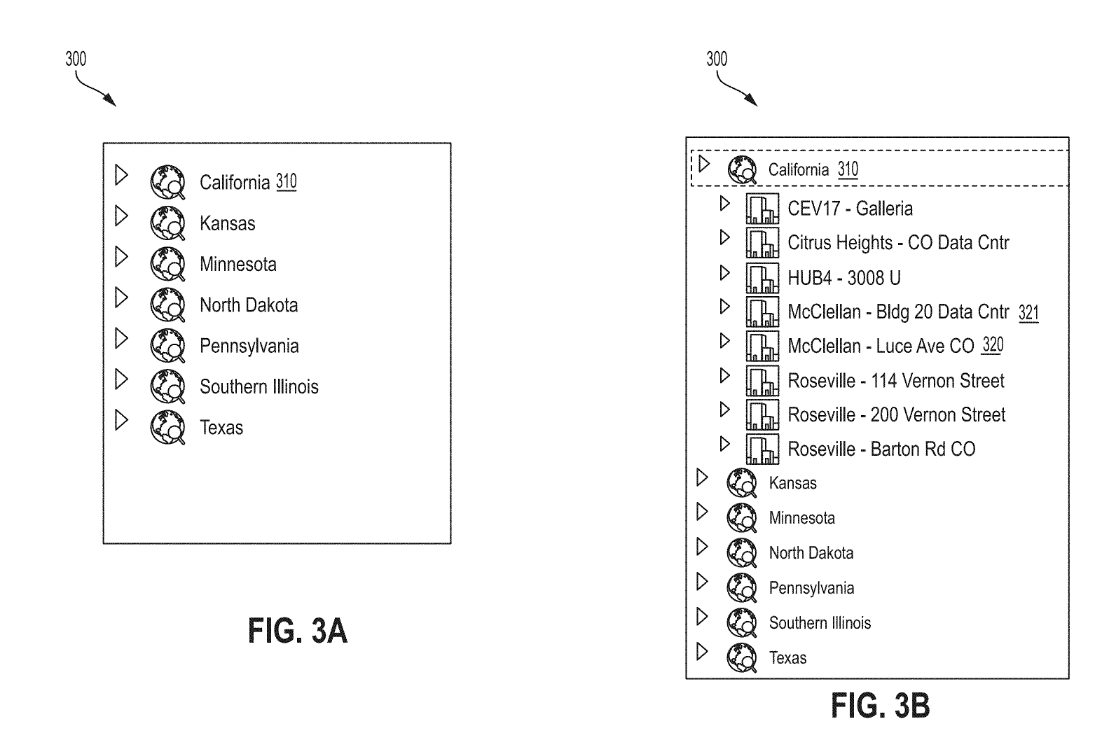

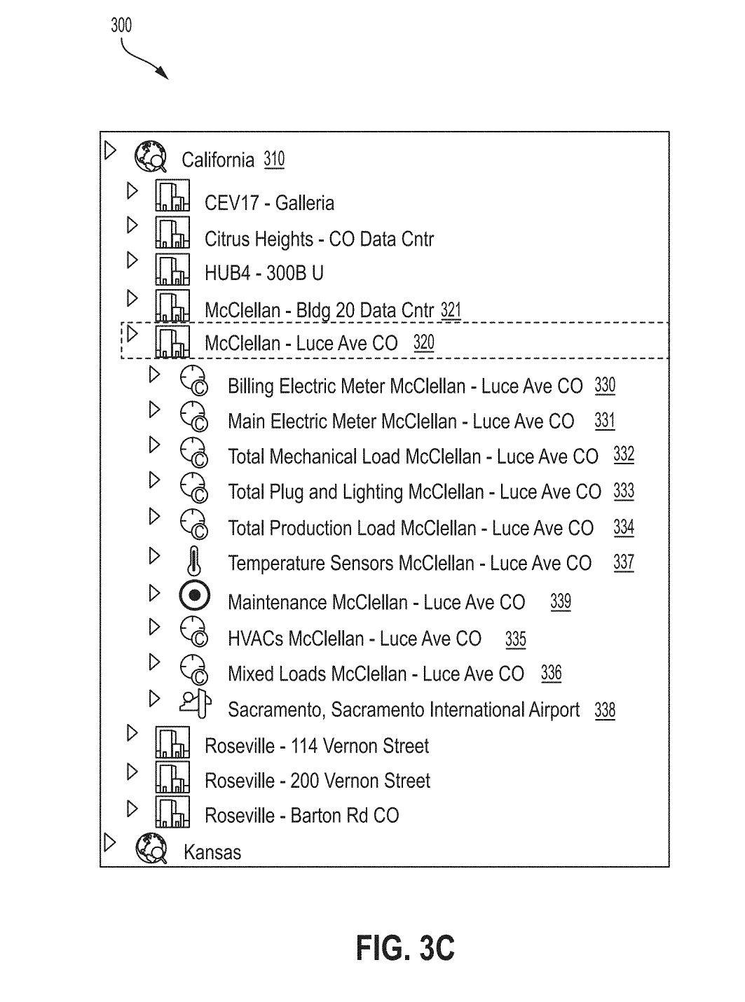

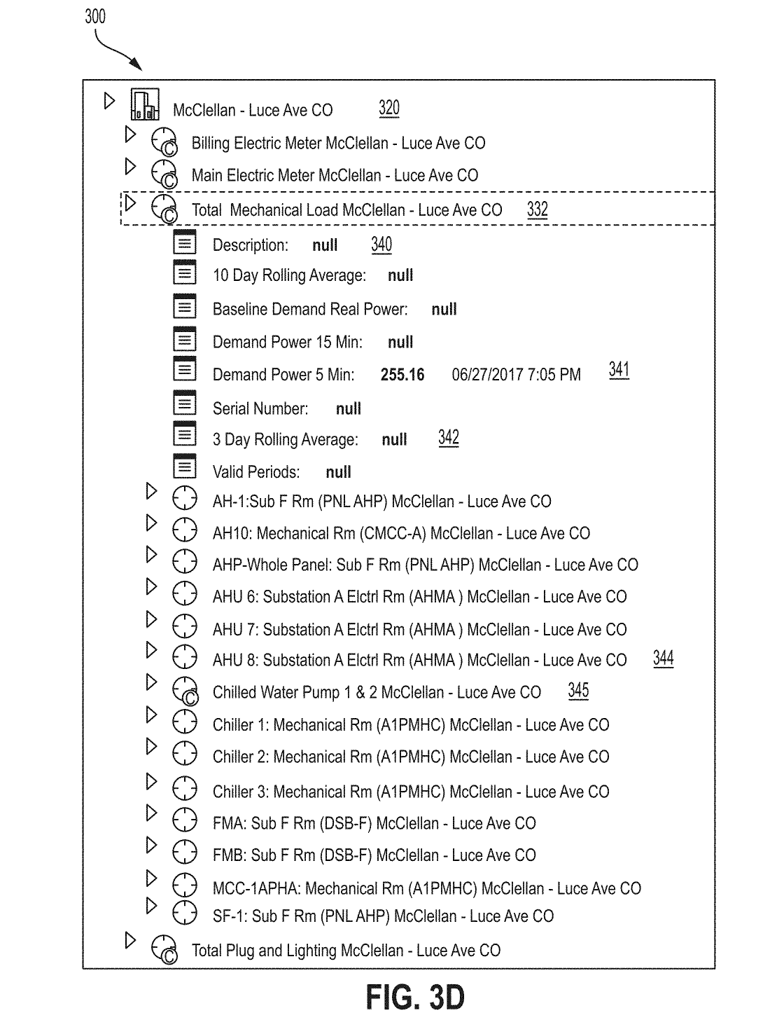

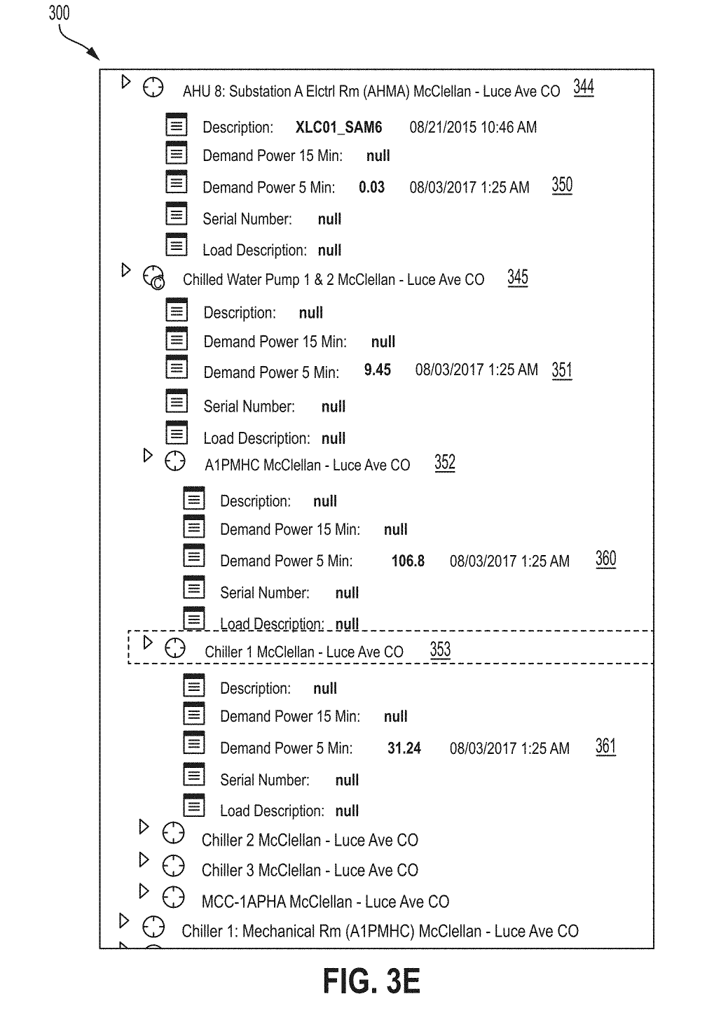

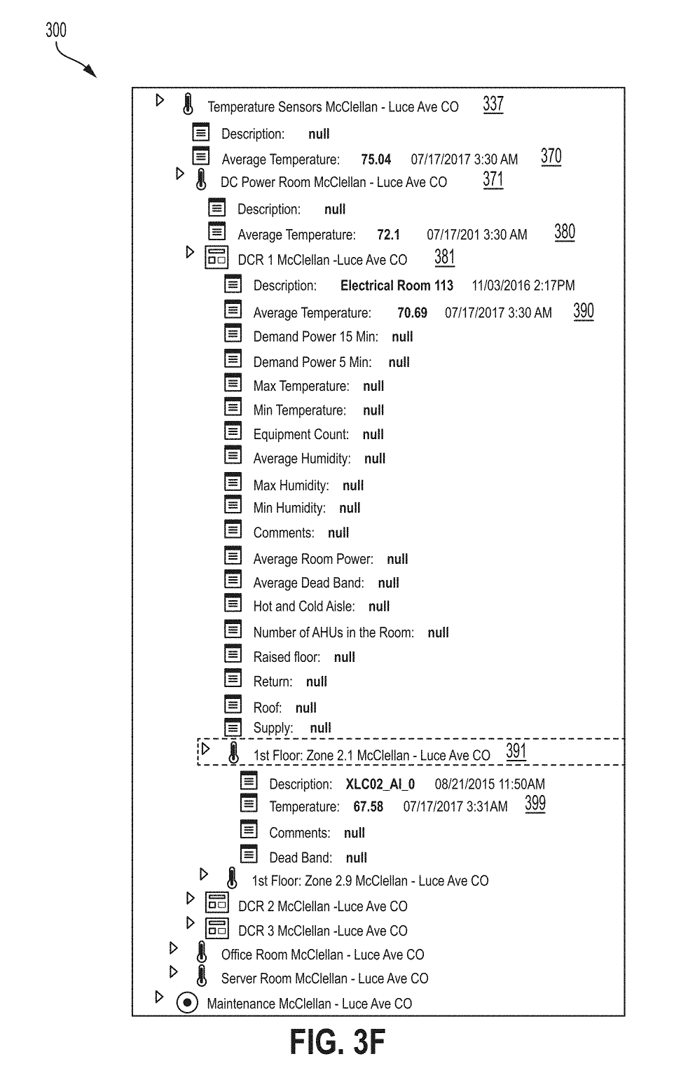

The inventors have recognized and appreciated that availability of more data may provide a fuller picture of what is happening at a facility. This may allow a consumption management system to perform analysis in a more fine grained manner, which may in turn lead to improved energy efficiency. However, the inventors have also recognized and appreciated that over-instrumentation may be costly, and may increase data volume and/or complexity. Increased data volume and/or complexity may prevent a consumption management system from performing certain analyses in real time, which may delay recommendations that would have reduced resource consumption. Accordingly, in some embodiments, sensors may be deployed in a structured manner to facilitate efficient processing and/or storage of data. Examples of structured deployment of sensors are discussed below in connection with FIGS. 2B, 3A-3F.

In some embodiments, the facility 110 may include one or more computing devices configured to interface with, respectively, one or more of the data sources 115, 116, . . . For instance, the data sources 115, 116, . . . may produce data in differing formats and/or transmit data using differing protocols. Examples of native formats include, but are not limited to, Comma Separated Values (CSV) files, Remote Terminal Unit (RTU) data, etc. Examples of protocols include, but are not limited to HTTP, HTTPs, TCP/IP, serial communication protocols, BACnet, Modbus TCP/IP, etc. Accordingly, a computing device at the facility 110 may execute selected driver software, and/or include selected hardware, to receive and/or appropriately interpret data from a certain data source.

In some embodiments, a plurality of drivers may process native data from, respectively, a plurality of data sources that utilize different data formats and/or different transmission protocols, and may produce data having a common format (e.g., a data record format containing multiple data fields), for example, using appropriate interface protocols. Thus, the drivers may convert native data from disparate sources into standardized data, which may be more readily consumed by the consumption management system 100. In this manner, the consumption management system 100 may be programmed to execute on incoming data irrespective of how, or by what device, the data was produced. Such an approach may reduce a need for the consumption management system 100 to perform specialized data handling, which in turn may allow the consumption management system 100 to be deployed for any resource type, any enterprise, and/or any vertical.

In the example of FIG. 1, the consumption management system 100 includes a data import module 120, an event detection module 130, and a calculation manager module 150. Any one or more of these modules may be executed by one or more computing devices at the facility 110, or at a different physical location. For instance, in some embodiments, a server (or a cluster of servers) may execute the modules 120, 130, and 150.

In some embodiments, the data import module 120 may be programmed to cleanse data received from the data sources 115, 116, . . . For instance, the data import module 120 may be programmed to check and/or correct incoming data to ensure that data passed to one or more downstream modules meets some appropriate standard of validity. As an example, a data validity check may comprise application of one or more appropriate validity rules to determine whether a valid data value is provided for a data field. Examples of validity rules include, but are not limited to, rules relating to expected data type, expected data range (e.g., temperature values below −50° C., a weight less than zero, a negative power demand, a value that is more than some number, say, 10, standard deviation away from a rolling average such as a 3-day average or a 10-day average, etc., may be considered invalid), presence of expected data values, sudden change in data values (e.g., increase between consecutive samples larger than certain threshold, say, 200%, may be considered invalid), etc., and suitable combinations thereof.

In some embodiments, the data import module 120 may be programmed to take one or more corrective actions in response to identifying an invalid or missing data value (also referred to herein as a “defect”). As one example, an invalid or missing data value in a data field may be addressed by contacting an appropriate data source and attempting to correct or recover the data value, if possible. As another example, an invalid or missing data value in a data field may be addressed using a selected constant value for that data field (e.g., some nominal value for the data field). As another example, an invalid or missing data value in a data field may be addressed using a value produced by interpolating (or otherwise predicting from) other data values of the same data field (e.g., from one or more data values produced earlier and/or one or more data values produced later).

As another example, an invalid or missing data value may be addressed using an historically-appropriate value based on an expectation that the data value would have, if present and valid, been similar to historical observations. For instance, an invalid or missing data value may be addressed using a data value obtained for the same data field at an earlier time, such as the same time a day earlier, or a week earlier. In some embodiments, an historically-appropriate value may be used, in some embodiments, only when certain conditions are met, such as when the earlier time was similar in some manner to a time of the invalid or missing data value based on one or more external factors (e.g., correct a resource consumption data value with a historical data value only when the weather is similar on both days). For instance, a linear regression expression on degree days or opening hours may be used, or a previous time period may be selected that has similar conditions (e.g., no more than a maximum allowed difference for each correlated parameter).

It should be appreciated that aspects of the present disclosure are not limited to taking any particular type of corrective action, or any corrective action at all. In some embodiments, an appropriate corrective action may be selected based on one or more factors, such as a type of a data field exhibiting a defect and/or a type of the defect.

In the example of FIG. 1, the data import module 120 is programmed to populate one or more hierarchical data structures, such as the object tree 170, based on data received from the data sources 115, 116, . . . The inventors have recognized and appreciated that, while one or more databases may be used to store the received data, database queries may be slow, which may negatively impact response time of the consumption management system 100. For instance, when a user requests certain information (e.g., average daily resource consumption over a certain past period of time for a certain load type, such as refrigeration, in a certain geographical region), the consumption management system 100 may query one or more databases to retrieve relevant data (e.g., hourly consumption values for individual refrigeration units in all sites in the specified geographical region within the specified period of time), and perform one or more calculations on retrieved data to provide the requested information (e.g., aggregating hourly consumption values for individual refrigeration units into daily consumption values, then aggregating across all refrigeration units at each site, then aggregating across all sites in the specified geographical region, and then averaging over the specified period of time). It may take the consumption management system 100 quite some time to respond (e.g., several seconds or tens of seconds) due to a large number of database queries and/or calculations that may be performed. Accordingly, in some embodiments, a hierarchical data structure may be used organize data in a manner that facilitates rapid retrieval.

The inventors have recognized and appreciated certain commonalities in how resources are consumed across different enterprises in different verticals. For instance, regardless of which vertical an enterprise is in, the enterprise may include one or more sites, which may be grouped by geographical location (e.g., country, region, state, county, city, neighborhood, etc.). A site may consume one or more types of resources (e.g., gas, electricity, water, etc.), and may include one or more buildings. A building may house one or more pieces of resource consuming equipment, which may be grouped based on load type (e.g., lighting, refrigeration, HVAC, mechanical load, etc.). A piece of resource consuming equipment (also referred to herein as an “asset”) may have one or more associated properties, such as a static property (e.g., name, serial number, installation date, etc.), a dynamic property (e.g., for a boiler, supply temperature, return temperature, set point, demand power, etc.), and/or a derived property (e.g., cumulative energy consumption in current day, week, month, year, or some other suitable period). Thus, in some embodiments, a hierarchical data structure, such as the object tree 170 in the example of FIG. 1, may be used to model resource consumption within an enterprise, regardless of which vertical the enterprise is in.

The inventors have recognized and appreciated that a hierarchical data structure may be accessed more efficiently than a database. Furthermore, the inventors have recognized and appreciated that a derived property of an asset may be updated as relevant data is received through the data import module 120. In this manner, a most up-to-date value of the derived property may always be available, so there may be no need to calculate such a value when a user request is received. One or both of these techniques (i.e., hierarchical data structure and/or derived property) may be used to reduce response time of the consumption management system 100. However, it should be appreciated that neither technique is required.

In the example of FIG. 1, the calculation manager module 150 may be programmed to perform one or more calculations based on data values received from the data import module 120, and to store results of said calculations in the facility data store 160. Additionally, or alternatively, the calculation manager module 150 may store results of calculations in the object tree 170. For instance, in some embodiments, the calculation manager module 150 may calculate a most up-to-date value of a derived property of an asset in the object tree 170, as discussed above. Additionally, or alternatively, the calculation manager module 150 may perform aggregations by traversing the object tree 170 (e.g., aggregating consumption of all refrigeration units within a building, site, region, etc.).

The calculation manager module 150 may be programmed to calculate any suitable type of derived quantity. For instance, the calculation manager module 150 may be programmed to evaluate a function of one or more data fields. This may include accessing current values of the one or more data fields, and performing one or more arithmetic operations on those values and/or one or more constant values. For instance, a derived quantity Q may be calculated by the calculation manager module 150 as:

Q=0.3×(Value of Data Field A)+(Value of Data Field B).

In some embodiments, a data field value used by the calculation manager module 150 to calculate a derived quantity may itself also be a derived quantity. For instance, a derived normalized electricity consumption value may be calculated by the calculation manager module 150 by dividing a data value indicating electricity consumption for a given physical space by a data value indicating a size of the physical space (e.g., producing a value in units of kWh/m2), where the data value indicating electricity consumption for the physical space may itself be calculated by the calculation manager module 150 as a sum of electricity consumption of all electrical appliances located in the physical space.

The inventors have recognized and appreciated that the calculation manager module 150 may be used, in some embodiments, to ensure that certain performance indicators (such as the normalized electricity consumption value discussed above) are constantly (or periodically) updated as new data arrives, so that most up-to-date values of the performance indicators are always readily available. This may reduce response time of the consumption management system 100 by reducing on-the-fly calculations when a user requests such performance indicators (e.g., to determine how efficiently aspects of an enterprise's operation are functioning).

In some embodiments, the calculation manager module 150 may be programmed to calculate and/or store historical data for one or more data fields. For instance, it may be desirable to track data values produced by one or more of the data sources 115, 116, . . . over a period of time (e.g., past week, month, year, etc., or some other suitable period). Such data values may be stored in the facility data store 160 as received from the data import module 120. Additionally, or alternatively, derived data values may be calculated and stored as historical data. For example, the calculation manager module 150 may access hourly values of electricity consumption recorded within a past week for a given physical space, and may sum those values to yield a cumulative consumption value for the past week. The cumulative consumption value (which may be stored as a derived quantity, or merely utilized in a present calculation) may be divided by 7 (representing days in a week), and by a data value indicating a size of the physical space, to produce a normalized daily average consumption value (e.g., in units of kWh/Day/m2).

In the example of FIG. 1, the event detection module 130 is programmed to compare received data values with predetermined set points to determine whether an anomaly has occurred. In some embodiments, a set point may represent a desired operating state of an asset. For instance, the set point may be chosen to improve resource utilization. An anomaly may be triggered if the asset is programmed to operate above (or below) the set point. When an anomaly is identified, an event is generated in event data 140, which comprises information about the anomalous event.

As referred to herein, an anomaly encompasses any observance of one or more data values that are in some way unexpected given historical or otherwise anticipated values of the relevant data fields. Any number of set points for a data field may be set based on such expectations so that, if values of the data field deviate from the defined set point(s), event detection module 130 may produce an event comprising details about said deviation. Multiple types of anomalies and therefore multiple set points may be set for a given data field or combination of data fields. For example, a data field representing a water flow rate through a pump may have a set point set so that if the water flow rate falls to zero (or close to zero), event detection module 130 may generate an event indicating that the pump may be inoperable. In addition, a set point may be set for the same data field as a range of water flow rates that represent nominal flow values for the pump. If the water flow rate is measured to be outside of this range, event detection module 130 may generate an event indicating an anomaly in the water flow rate that is different from the event indicating a potentially inoperable pump.

According to some embodiments, the event detection module 130 executes a rules engine that examines incoming data values to determine what occurred that gave rise to the anomaly whilst also calculating cost savings associated with correction of the anomaly. The rules engine may be configured based on expected cost savings for a particular customer so that the conditions that, when evaluated, determine that an anomaly has occurred also calculate expected cost savings associated with correction of the anomaly based on these conditions. For instance, based on the above example of a water pump, when the rules engine determines that the water flow rate has fallen to zero, the expected savings may be simultaneously calculated based on the expected cost of replacing or repairing the water pump, whereas when the rules engine alternatively determines that the water flow rate is measured to be outside of the range set point, the expected savings may be simultaneously calculated based on how much money would be saved were the water flow rate adjusted to be within the range. In the latter case, calculations of expected savings may, for example, take into account expected effects on other parts of the facility that are causally linked with the water pump (e.g., up- or downstream parts), costs of performing adjustments on the system, expected changes in lifetime of the pump, etc.

In the example of FIG. 1, the query interface 180 may be programmed to access the object tree 170, the facility data store 160, and/or the event data store 140. For instance, the query interface 180 may include a query API that may be used by other components of the consumption management system 100 to run queries against stored data.

In some embodiments, the query interface 180 may include one or more user interfaces configured to allow a user to browse some or all of the stored data. For instance, the query interface 180 may include a web-based thin client programmed to provide various user interfaces via a web browser. A web server may formulate a query based on user input received via the web browser and one or more networks, issue the query via the query API, and transmit a result of the query to the web browser via the one or more networks. The web browser may present the result to the user. Additionally, or alternatively, the query interface 180 may include a mobile device app programmed to provide various user interfaces. The mobile device app may formulate a query based on user input, transmit the query via one or more networks to the query API, receive a result of the query via the one or more networks, and present the result to the user.

In some embodiments, access to the object tree 170, the facility data store 160, and/or the event data store 140 may be controlled via one or more suitable access control mechanisms. For instance, a first enterprise may have multiple facilities. A user at a certain facility may be granted access only to data pertaining to that facility, whereas a user at a headquarters may be granted access to data pertaining to all facilities within the first enterprise. On the other hand, a user from a second enterprise may be granted access only to data pertaining to the second enterprise, and may not be granted access to any data pertaining to the first enterprise.

Although various details of implementation are shown in FIG. 1 and discussed above, it should be appreciated that aspects of the present disclosure are not limited to the use of any particular component, or combination of components, or to any particular arrangement of components. For instance, it should be appreciated that the object tree 170, the facility data store 160, and/or the event data store 140 may be stored within a same database, in any number of different databases, or represented in any other suitable manner, such as by storing data in flat files (e.g., XML files). Furthermore, each component may be implemented in any suitable manner, such as using one or more parallel processors operating at a same location or different locations.

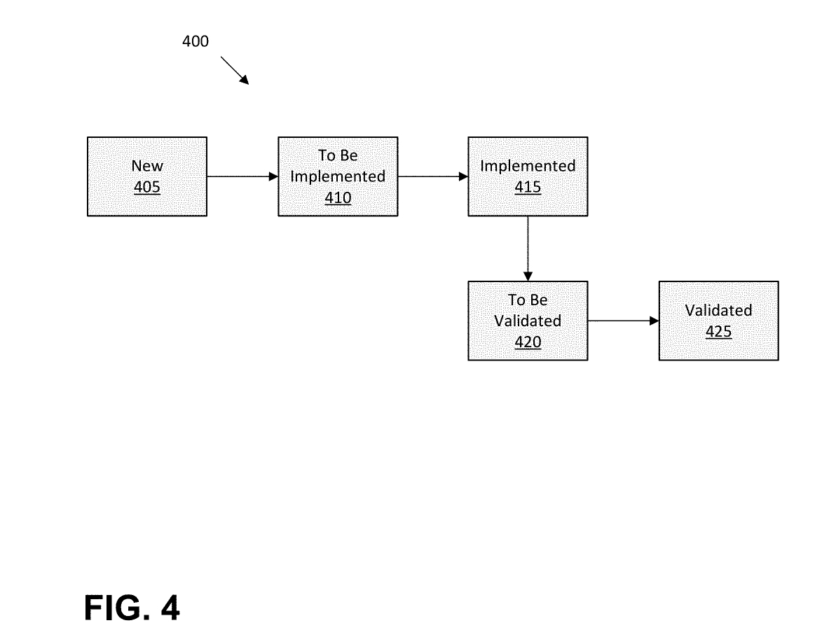

FIGS. 2A-2B show, respectively, an illustrative virtual meter 210 and an illustrative virtual meter 252, in accordance with some embodiments. In the example of FIG. 2A, a sensor may be installed at each of a plurality of lighting units to measure electricity consumption of that unit. These sensors may correspond, respectively, to sub meters 211, 212, 213, . . . shown in FIG. 2A. A virtual lighting meter, shown as main meter 210 in FIG. 4A, may be obtained by summing electricity consumption measurements from the individual lighting units. In some embodiments, values provided by the virtual lighting meter may be stored in an object tree, as discussed in detail in connection with FIGS. 3A-3F.

In the example of FIG. 2B, an electric panel may serve a refrigeration unit and multiple lighting units. A first sensor may be installed to measure electricity consumption of the electric panel (i.e., combined electricity consumption of the refrigeration unit and the multiple lighting units), and a second senor may be installed to measure electricity consumption of the refrigeration unit alone. The first and second sensors may correspond, respectively, to main meter 250 and sub meter 251 shown in FIG. 2B. A virtual lighting meter, shown as residual meter 252 in FIG. 2B, may then be obtained by subtracting the refrigeration unit's electricity consumption measurement from the combined consumption measurement. However, it should be appreciated that aspects of the present disclosure are not limited to the use of a virtual meter to obtain a consumption value, as in some embodiments a site may have a main switch board feeding all equipment of a certain type (e.g., mechanical, lighting, etc.), and a sensor may be installed at the main switch board to obtain a consumption value for that equipment type.

In some embodiments, a virtual data source (e.g., the illustrative virtual meter 210 in the example of FIG. 2A, or the illustrative virtual meter 252 in the example of FIG. 2B) may be calculated by one or more computing devices located at a facility (e.g., executing appropriate driver software). Alternatively, or additionally, a virtual data source may be calculated by a component of a consumption management system (e.g., the illustrative calculation manager module 150 in the example of FIG. 1), which may execute on one or more computing devices located remotely from the facility.

The inventors have recognized and appreciated that virtual data sources may be used to provide flexibility in how data is collected and/or analyzed. For instance, in the example of FIG. 2B, there may be a large number of individual lighting units, and it may be costly to install a sensor at each lighting unit. Therefore, it may be more cost effective to measure the combined electricity consumption of the refrigeration unit and the multiple lighting units, and then subtract the electricity consumption of the refrigeration unit, even though the combined electricity consumption measurement, by itself, may be not useful to a consumption management system (e.g., because the combined electricity consumption measurement mixes two different consumption categories, refrigeration and lighting). Moreover, the use of a virtual data source may improve transparency. For instance, a component of a consumption management system that uses a virtual data source may be unaffected by changes in how the virtual data source is implemented. However, it should be appreciated that aspects of the present disclosure are not limited to the use of a virtual data source.

FIGS. 3A-3F show an illustrative object tree 300 for organizing resource consumption data, in accordance with some embodiments. For instance, the object tree 300 may be a portion of the illustrative object tree 170 in the example of FIG. 1, and may be used to model resource consumption within an enterprise.

As discussed above, the inventors have recognized and appreciated certain commonalities in how resources are consumed across different enterprises in different verticals. The inventors have further recognized and appreciated that these commonalities may be exploited to provide a hierarchical structure that may be easily adapted for any enterprise in any vertical. For instance, an enterprise may operate one or more sites, which may be grouped by geographical region. Accordingly, in the example of FIG. 3A, the object tree 300 includes a plurality of nodes corresponding respectively to different geographical regions, such as a node 310 corresponding to California. In some embodiments, each node corresponding to a geographical region may have one or more child nodes corresponding, respectively, to different sites located in that region. For instance, in the example of FIG. 3B, the node 310 has a plurality of child nodes corresponding, respectively, to different sites located in California, such as a node 320 corresponding to a site named “McClellan—Luce Ave CO.”

The inventors have recognized and appreciated that sites within the object tree 300 may be organized in a manner that matches an enterprise's organizational structure (e.g., grouped by geographical region), so that a user already familiar with the enterprise's organizational structure may be able to quickly find a site within the object tree 300. However, it should be appreciated that aspects of the present disclosure are not limited to grouping sites in any particular manner, or any grouping at all. For instance, in some embodiments, one or more sites may be found at a top level of an object tree (e.g., arranged in alphabetical order based on site name).

Furthermore, in some embodiments, a corporate branch within the enterprise's organizational structure may include multiple buildings or multiple groups of buildings, each of which may be represented by a different node in the object tree. For instance, in the example shown in FIG. 3C, the node 320 (“McClellan—Luce Ave CO”) and a node 321 (“McClellan—Bldg 20 Data Cntr”) may represent, respectively, different buildings at a same corporate branch (“McClellan”).

As discussed in connection with FIG. 1, the inventors have recognized and appreciated that a hierarchical data structure such as the object tree 300 shown in FIGS. 3A-3F may be used to organize information and facilitate rapid retrieval. Accordingly, in some embodiments, the node 320 (“McClellan—Luce Ave CO”) may have a plurality of child nodes representing different types of information of interest. For instance, there may be a “Billing Electric Meter” node 330 and a “Main Eletric Meter” node 332 corresponding, respectively, to electricity consumption at the site “McClellan—Luce Ave CO” as reported by a meter connected to a system of a resource provider (e.g., a utility company), and by a meter connected to a system of an enterprise operating the site or a consumption reduction service provider.

The inventors have recognized and appreciated it may be beneficial to break down total resource consumption into different categories based on a purpose for which resource is consumed (e.g., lighting, refrigeration, HVAC, mechanical load, etc.). This may allow a user to gain deeper insight into how resources are consumed, and to make different decisions for different categories of consumption. Accordingly, in the example of FIG. 3C, the node 320 (“McClellan—Luce Ave CO”) has a plurality of child nodes corresponding, respectively, to different load categories. For instance, there may be a “Total Mechanical Load” node 332 corresponding to consumption by mechanical equipment, a “Total Plug and Lighting” node 333 corresponding to consumption via electrical outlets, as well as consumption by lighting units, a “Total Production Load” node 334 corresponding to consumption by production equipment (e.g., assembly lines in a factory, ovens in a bakery, etc.), and an “HVACs” node 335 corresponding to consumption by HVAC equipment.

It should be appreciated that aspects of the present disclosure are not limited to tracking consumption by any particular load category, or by any load category at all. For instance, in the example of FIG. 3C, the node 320 (“McClellan—Luce Ave CO”) has a child node 336 (“Mixed Loads”) corresponding to consumption by multiple pieces of equipment belonging to different load categories. Such a node may be created for any suitable reason. As an example, there may be one physical meter measuring collective consumption by the multiple pieces of equipment, and it may be too costly to install separate meters to segregate the different load categories. As another example, a user may simply wish to track these pieces of equipment together for administrative purposes. Thus, a piece of equipment may be tracked under different child nodes of the node 320 (“McClellan—Luce Ave CO”). For instance, a same piece of mechanical equipment may be tracked under the node 336 (“Mixed Loads”), as well as the node 332 (“Total Mechanical Load”).

The inventors have further recognized and appreciated it may be beneficial to maintain data relating to one or more aspects of a site's operation. For example, such data may be used to identify opportunities to reduce resource consumption while maintaining a desired state of operation. Accordingly, in some embodiments, one or more sensors and/or interfaces to existing instruments may be installed at a site to collect measurements. Data obtained from these measurements may be stored in the object tree 300 for ready access. For instance, in the example of FIG. 3C, the node 320 has a child node 337 (“Temperature Sensors”) corresponding to temperature sensors installed at the site “McClellan—Luce Ave CO.”

It should be appreciated that aspects of the present disclosure are not limited to the use of any particular type of sensor or other instrument. In some embodiments, measurements may be collected using different types of sensors having different functionalities (e.g., for measuring temperature, humidity, pressure, etc.), and the node 320 (“McClellan—Luce Ave CO”) may have different child nodes corresponding, respectively, to the different types of sensors (e.g., a temperature sensors node, a humidity sensors node, a pressure sensors node, etc.). However, it should be appreciated that aspects of the present disclosure are not limited to grouping sensors and/or other instruments by functionality, as any other suitable grouping may be used, or no grouping at all.

The inventors have further recognized and appreciated it may be beneficial to maintain data relating to one or more variables that may impact resource consumption. For example, such data may be used to accurately determine savings resulting from implementing one or more consumption reduction measures. Accordingly, in some embodiments, the node 320 may have different child nodes corresponding, respectively, to different types of variables that may impact resource consumption at the site “McClellan—Luce Ave CO.” For instance, in the example of FIG. 3C, the node 320 has a child node 338 (“Sacramento—Sacramento International Airport”) corresponding to weather conditions reported by a weather station located near the site “McClellan—Luce Ave CO.” Although not shown, other types of variables (e.g., production volume, rates charged by utility companies, etc.) may be tracked in addition to, or instead of, weather.

In some embodiments, there may be a “Maintenance” node 339, which may store all data from various data sources. In this manner, a failure may be readily identified (e.g., a particular sensor that failed to provide a meaningful output).

In some embodiments, each child node of the node 320 (“McClellan—Luce Ave CO”) may have one or more associated properties, such as a static property, a dynamic property, and/or a derived property. A static property may have a value that is not expected to change over time, such as name, serial number, installation date, etc. A dynamic property may be expected to have different values over time, such as demand power. Such values may be updated continually based on information received from data sources such as the illustrative data sources 115, 116, . . . in the example of FIG. 1. A derived property may have values derived in any suitable manner, for example, based on one or more values of static properties, dynamic properties, and/or other derived properties in the object tree 300, and/or values persisted in a data store such as the illustrative facility data store 160 in the example of FIG. 1.

In the example of FIG. 3D, the node 332 (“Total Mechanical Load”) has a plurality of static properties (e.g., “Description” 340) and a plurality of derived properties (e.g., “Demand Power 5 Min” 341 and “3 Day Rolling Average” 342 of demand power). A derived property may be computed from data available from the object tree 300. However, it should be appreciated that these properties are shown and described solely for purposes of illustration, as aspects of the present disclosure are not limited to tracking any particular property.

In some embodiments, the node 332 (“Total Mechanical Load”) may correspond to a physical meter measuring consumption of all mechanical equipment at the site “McClellan—Luce Ave CO.” The inventors have recognized and appreciated that installation of such a meter may require significant electrical work (e.g., re-wiring), and therefore may be costly or even impractical. Accordingly, in some embodiments, the node 332 (“Total Mechanical Load”) may instead correspond to a virtual meter that is a sum of a plurality of sub-meters, and may have a plurality of child nodes corresponding, respectively, to the plurality of sub-meters. In the example of FIG. 3D, the node 332 (“Total Mechanical Load”) has a plurality of child nodes including a node 344 (“AHU 8: Substation A Elctrl Rm (AHMA)”) corresponding to a sub-meter for a particular room at the site “McClellan—Luce Ave CO,” and a node 345 (“Chilled Water Pump 1 & 2”) corresponding to a sub-meter for two chilled water pumps at the site “McClellan—Luce Ave CO.”

In some embodiments, the node 344 (“AHU 8: Substation A Elctrl Rm (AHMA)”) may correspond to a physical meter measuring consumption of all mechanical equipment located in the associated room, and may have one or more static, dynamic, and/or derived properties. In the example of FIG. 3E, the node 344 (“AHU 8: Substation A Elctrl Rm (AHMA)”) has a plurality of properties including a dynamic property “Demand Power 5 Min” 350, which may be updated based on data received from the physical meter corresponding to the node 344 (“AHU 8: Substation A Elctrl Rm (AHMA)”).

By contrast, in the example of FIG. 3E, the node 345 (“Chilled Water Pump 1 & 2”) corresponds to a virtual meter that is a sum of a plurality of sub-meters. Thus, in addition to a plurality of static, dynamic, and/or derived properties (e.g., a derived property “Demand Power 5 Min” 351), the node 345 (“Chilled Water Pump 1 & 2”) may have a plurality of child nodes corresponding, respectively, to the plurality of sub-meters. For instance, the node 345 (“Chilled Water Pump 1 & 2”) may have five child nodes, including a node 352 (“A1PMHC”) and a node 353 (“Chiller 1”).

In some embodiments, each child node of the node 345 (“Chilled Water Pump 1 & 2”) may have one or more static, dynamic, and/or derived properties. For instance, in the example of FIG. 3E, the node 352 (“A1PMHC”) has a plurality of properties including a dynamic property “Demand Power 5 Min” 360, which may be updated based on data received from a physical meter corresponding to the node 352 (“A1PMHC”). Likewise, the node 353 (“Chiller 1”) has a plurality of properties including a dynamic property “Demand Power 5 Min” 361, which may be updated based on data received from a physical meter corresponding to the node 353 (“Chiller 1”).

The inventors have recognized and appreciated various advantages of a hierarchical data structure such as the object tree 300 shown in FIGS. 3A-3F. For instance, the object tree 300 may be constructed to reflect a logical organization that may be intuitive to a user. In some embodiments, a user interface may be provided (e.g., by the illustrative query interface 180 in the example of FIG. 1) according to the object tree 300. Such a user interface may allow a user to easily “zoom in” from a higher level in the object tree 300 to a lower level (e.g., from region to site, to particular load category, to sub-meter, and then to physical meter or individual asset). Likewise, a user may be able to easily “zoom out” from a lower level in the object tree 300 to a higher level.

The inventors have further recognized and appreciated that a hierarchical data structure such as the object tree 300 shown in FIGS. 3A-3F may be used to facilitate aggregation of data. For instance, instead of storing raw data in a database and performing on-demand queries to aggregate data, certain statistics of interest may be stored in the object tree 300 and may be constantly or periodically updated as new data arrives. In this manner, the statistics of interest may be readily available, which may improve response time when a user requests certain information.

In some embodiments, updating a statistic may involve a traversal of the object tree 300, aggregating relevant values from leaf nodes upwards to a node of interest. As an example, to update the derived property “Demand Power 5 Min” 341 of the node 332 (“Total Mechanical Load”), demand power values may be accessed from all leaf nodes under the node 332 (“Total Mechanical Load”). For instance, demand power values may be accessed from all five child nodes of the node 345 (“Chilled Water Pump 1 & 2”), including the dynamic property “Demand Power 5 Min” 360 of the node 352 (“A1PMHC”) and the dynamic property “Demand Power 5 Min” 361 of the node 353 (“Chiller 1”). These values may be summed and stored as the derived property “Demand Power 5 Min” 351 of the node 345 (“Chilled Water Pump 1 & 2”). This may in turn be aggregated with the dynamic property “Demand Power 5 Min” 350 of the node 344 (“AHU 8: Substation A Elctrl Rm (AHMA)”), as well as demand power values from other child nodes of the node 332 (“Total Mechanical Load”), to provide a value for the derived property “Demand Power 5 Min” 341 of the node 332 (“Total Mechanical Load”).

In some embodiments, total demand power for a site may be obtained by aggregating demand power values from different load categories that are present at the site. Likewise, total demand power for a geographical region may be obtained by aggregating demand power values from different sites located in that region.

The inventors have recognized and appreciated that, when a derived property is updated, it may be beneficial to store one or more immediate results in the object tree 300. For instance, as discussed above, a sum of demand power values from all five child nodes of the node 345 (“Chilled Water Pump 1 & 2) may be stored as the derived property “Demand Power 5 Min” 351, even though an ultimate goal is to update the derived property “Demand Power 5 Min” 341 of the node 332 (“Total Mechanical Load”). In this manner, when the derived property “Demand Power 5 Min” 351 is needed for another purpose, its value may simply be looked up from the object tree 300, without having to repeat the computation already performed (unless the value has become stale). In some embodiments, a derived property may be re-computed in response to detecting and correcting an error in a data source from which the derived property depends.

Referring to FIG. 3F, the node 337 (“Temperature Sensors”) may have one or more static, dynamic, and/or derived properties (e.g., a derived property “Average Temperature” 370), and/or one or more child nodes (e.g., a “DC Power Room” node 371) corresponding, respectively, to different areas within the site “McClellan—Luce Ave CO.” Each child node may in turn have one or more static, dynamic, and/or derived properties, and/or one or more child nodes corresponding, respectively, to different sub-areas. For instance, in the example of FIG. 3F, the node 371 (“DC Power Room”) has a plurality of properties including a derived property “Average Temperature” 380, and a plurality of child nodes including a child node 381 (“DCR 1”). The child node 381 (“DCR 1”) in turn has a plurality of properties including a derived property “Average Temperature” 390, and a plurality of child nodes corresponding, respectively, to different physical temperature sensors. For example, a child node 391 (“1st Floor—Zone 2.1”) corresponds to a physical temperature sensor, and has a plurality of properties including a dynamic property “Temperature” 399, which may be updated based on data received from the physical temperature sensor.

As with resource consumption data, the inventors have recognized and appreciated that arranging sensor data in a hierarchical manner may advantageously allow a user to easily “zoom in” or “zoom out” to view relevant information at different levels. Also, relevant information (e.g., average temperature) may be aggregated by traversing the hierarchical structure, for example, from physical temperature sensor readings (e.g., the dynamic property “Temperature” 399 of the node 391), to sub-area averages (e.g., the derived property “Average Temperature” 390 of the node 381), to area averages (e.g., the derived property “Average Temperature” 380 of the node 371), and then to site average (e.g., the derived property “Average Temperature” 370 of the node 337). One or more of the intermediate values may be stored for later use.

Although consumption data is organized based on load category in the illustrative object tree 300, it should be appreciated that aspects of the present disclosure are not so limited. In some embodiments, consumption data may be organized based on equipment type (e.g., AC units, heating furnaces, pumps, water heaters, lighting fixtures, refrigerators, ovens, etc.) in addition to, or instead of, load category. Accordingly, a hierarchical structure similar to the illustrative object tree 300 may be constructed that includes nodes corresponding respectively to different equipment types (e.g., an “AC Units” child node, a “Water Heaters” child node, a “Pumps” child node, etc.) This may advantageously allow aggregation of consumption data by equipment type (e.g., total demand power from all AC units). However, it should be appreciated that aspects of the present disclosure are not limited to organizing consumption data based on equipment type.

Furthermore, although examples are provided relating to consumption of electricity, a consumption management system may manage one or more other types of resources in addition to, or instead of, electricity. For instance, the illustrative object tree may be augmented to include a “Billing Gas Meter” node corresponding to total natural gas consumption, a “Billing Water Meter” corresponding to total water consumption, etc., in addition to the “Billing Electric Meter” node 330. Pieces of equipment that consume natural gas, water, etc. may be organize in any suitable manner (e.g., by load category, equipment type, location, sub-meter, etc.).

The inventors have further recognized and appreciated that a hierarchical data structure such as the object tree 300 shown in FIGS. 3A-3F may be used to reduce instrumentation, which may reduce costs, and/or data volume and/or complexity. For instance, certain asset types (e.g., lighting) may include units that are too numerous to monitor individually. Such units may be represented collectively in the object tree 300, and only one sensor may be installed to monitor collective behavior of all of the units. For instance, with reference to FIG. 3C, the node 333 (“Total Plug and Lighting”) may be a leaf node, and may have one or more properties but no child node.

Although various advantages of a hierarchical data structure is discussed above, it should be appreciated that aspects of the present disclosure are not limited to the use of a hierarchical data structure. Also, details of implementation are shown in FIGS. 3A-3F and described above solely for purposes of illustration. Aspects of the present disclosure are not limited to any particular design of an object tree (e.g., a number of levels, what is represented logically by each level, what data is stored, etc.).

FIG. 4 shows an illustrative state transition diagram 400 for a consumption management event, in accordance with some embodiments. For instance, a consumption management event (or “event” for short) may be detected by the illustrative event detection module 130 in the example of FIG. 1, and a corresponding record may be stored in the illustrative event data store 140 in the example of FIG. 1. Such a record may include one or more proposed measures for reducing resource consumption, and/or expected savings that may result from implementing the one or more consumption reduction measures.

In some embodiments, an event may transition through multiple states. For instance, in the example shown in FIG. 4, a newly detected event may begin in a state 405 (“New”), where the event may await a user's review. Once the user reviews and approves the event for implementation, the event may transition into a state 410 (“To Be Implemented”).

Implementation of a proposed consumption reduction measure may involve one or more actions such as upgrading one or more pieces of equipment (e.g., replacing fluorescent light fixtures with LED light fixtures that are more energy efficient), adjusting one or more operating parameters (e.g., temperature set points on thermostats), adjusting one or more operating schedules (e.g., when to turn pumps on/off), etc. Such an action may be performed by one or more employees of an enterprise operating a site at which the event is detected. However, that is not required, as in some embodiments one or more resource consumption consultants working for a third party vendor (e.g., a vendor that provides resource consumption consulting services via the illustrative consumption management system 100 in the example of FIG. 1) may take part in the implementation in addition to, or instead of, the one or more site employees.

In the example shown in FIG. 4, an event in the state 410 (“To Be Implemented”) may transition to a state 415 (“Implemented”) once the one or more proposed measures associated with the event have been implemented. In some embodiments, a user who did not take part in the implementation may verify that the one or more proposed measures have been correctly implemented. While the user performs this verification, the event may reside in a state 420 (“To Be Validated”), and may transition to a state 425 (“Validated”) once the validation is completed successfully.

The inventors have recognized and appreciated a state transition diagram such as the illustrative state transition diagram 400 may be used to track progress of implementation of consumption reduction measures. For instance, statistics may be collected regarding how long events reside in various states. Such statistics may be used to identify and correct potential workflow issues (e.g., insufficient staffing). However, it should be appreciated that aspects of the present disclosure are not limited to the use of any particular state transition diagram to track consumption management events, or any state transition diagram at all.

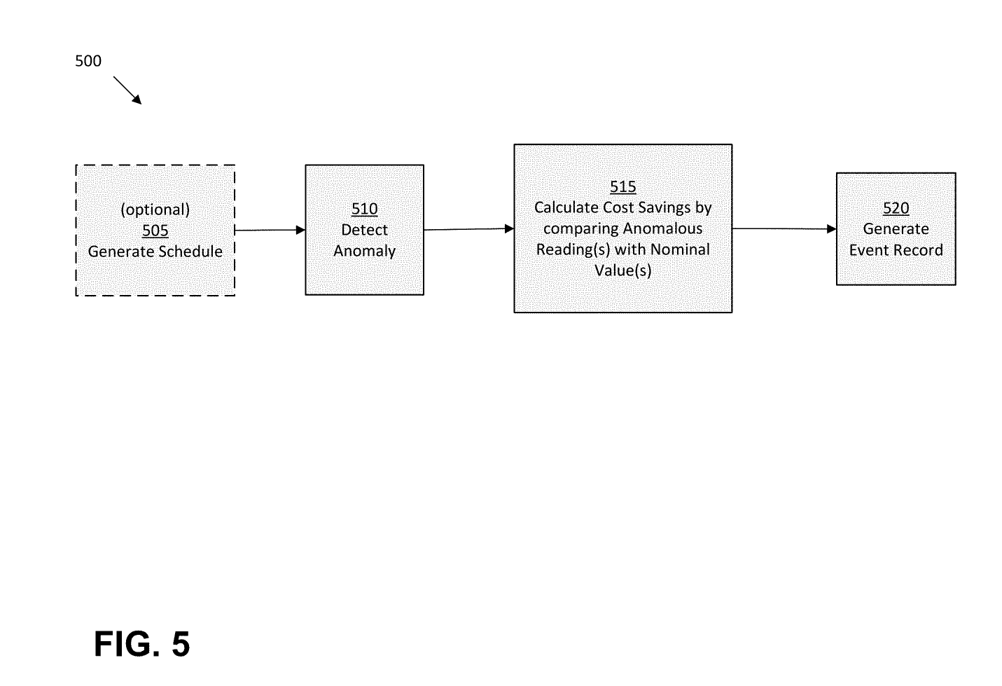

FIG. 5 shows an illustrative process 500 for detecting events and calculating cost savings for a consumption management system, in accordance with some embodiments. As discussed above, a consumption management system may be programmed to compare received data values with predetermined nominal values to detect anomalies in the device(s) and/or system(s) that produce the data values (for example, via event detection module 130 in the example of FIG. 1). Moreover, expected cost savings associated with correction of an anomaly may be calculated based on the received data values and the nominal values. Illustrative process 500 is one example of a process that is configured to perform such an analysis.

Illustrative process 500 optionally begins with act 505 in which a schedule is generated. In some embodiments, a schedule may be generated by a consumption management system for a facility wherein the schedule defines, at least in part, a recommended operational approach for the facility. The schedule may define values of one or more operational parameters of the facility at one or more time points over a given period of time (e.g., daily, hourly, weekly, etc.) that are expected to, if followed by the facility, be the most cost efficient manner of operation. As referred to herein, operational parameters of a facility describe various states of devices and/or systems at the facility, such as whether a device is on or off or a configurable setting for a device. A schedule that defines operational parameters over time thereby describes how to operate portions of a facility.

According to some embodiments, a schedule may be generated in act 505 by considering the cost effectiveness of operating the facility in various potential ways and, optionally, subject to certain constraints and/or limitations. For instance, a schedule may be generated for a facility that includes a lighting system, where the schedule dictates when various lights of the system should be turned on or off. In generating this schedule, the cost of energy necessary to power the various lights may be considered subject to constraints that certain lights are to be turned on at certain times to fulfill business needs.

According to some embodiments, generation of a schedule in act 505 may be based upon data representing one or more factors external to the customer facility. Such data may be stored in an object tree, discussed above, or otherwise obtained by the consumption management system when generating the schedule. Data representing one or more factors external to the customer facility may include any external factors that may affect the cost efficiency of a schedule such as, but not limited to, a cost of electricity or other consumable resource (which may vary by time and/or by day of the week, etc.); and/or weather conditions (expected and/or current).

According to some embodiments, generation of a schedule in act 505 may be based upon data representing one or more factors internal to the customer facility. Such data may be stored in an object tree, discussed above, or otherwise obtained by the consumption management system when generating the schedule. Data representing one or more factors internal to the customer facility may include any internal factors that may affect the cost efficiency of a schedule such as constraints on how a device or system at the facility may be operated (e.g., a range of possible operational cooling rates for an HVAC system, heating rates for a heating system, water flow rates for a pumping system, etc.) and/or limitations on how high or low a characteristic of the facility may be allowable (e.g., a lowest and/or highest allowable temperature for a room or other location, a lowest and/or highest allowable tank level for a water tank or gas tank, etc.).

According to some embodiments, generation of a schedule in act 505 may comprise calculating the lowest expected cost of operating the system by selecting operational parameters that minimize the cost. As discussed above, such a calculation may be further based on one or more constraints and/or limitations that define (or otherwise constrain and/or limit) how the operational parameters' values may be selected and may be performed via an optimization procedure or otherwise. The operational parameters may include any characteristics of one or more devices or systems at the customer facility that may be adjusted by the customer. In some cases, an operational parameter may have only two states, such as a light which may be adjusted to be on or adjusted to be off. In some cases, an operational parameter may define a heating or cooling rate of a heating and/or cooling system, a target temperature of a heating and/or cooling system, a pump rate of a water pump, etc. In some embodiments, a single device or system may have more than one operational parameter associated with it, such as an operational parameter that defines whether the device or system is active or inactive in addition to one or more other operational parameters that define settings of the device or system in the case that it is active.

According to some embodiments, an operational parameter may describe any aspect of the customer facility whose value implies physical settings for any number of devices or systems at the customer facility, and it need not necessarily be the case (although it may be) that the operational parameter corresponds to a physical setting on a physical device or system. For instance, an operational parameter that is a target temperature for a cooling system may correspond to a physical setting on the cooling system, i.e., a user at the customer facility may enter or otherwise adjust the cooling system to include this target temperature as a physical setting. Alternatively, an operational parameter of a closing time for a store may be not directly related to a physical setting because there may not be a physical device or system into which this time is entered. Nonetheless, various other settings (e.g., when lights are turned off) may be informed by the value of such an operational parameter and, as such, varying this type of operational parameter still has implications for the cost efficiency of the facility. In general, any number of any types of operational parameters may be evaluated when determining an optimal schedule of operational parameters in act 505.

Irrespective of whether a schedule is generated in act 505, in act 510 an anomaly is detected. As discussed above, an anomaly encompasses any observance of one or more data values that are in some way unexpected given historical or otherwise anticipated values of the relevant data fields. In some cases, a schedule generated in act 505 may provide the anticipated values in that the schedule is defined for a set operational parameters and detection of an anomaly may comprise determining whether or not the schedule is being followed by the system based on data values obtained from the facility (e.g., by comparing a scheduled cooling rate with an actual cooling rate performed by the system). In some cases, a result of such a comparison may be treated as an anomaly if the observed data value(s) deviate from one or more expected values by greater than some threshold (e.g., more than 10% different, etc.) or may be treated as an anomaly if there is any deviation at all (e.g., if a light is scheduled to be off, but is detected to be on). Comparisons of data values obtained from the facility with their anticipated values may be performed in real time as the data values are read by the consumption management system and/or periodically based on received data values (e.g., hourly, daily, etc.).

According to some embodiments, detection of an anomaly may comprise identifying that one or more data values deviated from their anticipated value over a period of time. As such, this period of time may be measured and associated with the anomaly. Data generated and stored by the consumption management system describing the anomaly may thereby include a measure of the period of the anomaly in addition to a measure of the deviation observed. In some cases, data generated and stored by the consumption management system describing the anomaly may comprise measures of deviation that occurred at a plurality of times during which an anomaly is detected to have occurred. For instance, a flow rate that is much higher than anticipated over a period of time may cause the consumption management system to detect an anomaly and store the flow rate at a number of times during the period in association with the anomaly.

In act 515, one or more estimates of cost savings are calculated by comparing obtained data values with their predetermined nominal values. Such nominal values may be defined by the consumption management system via a predetermined schedule or otherwise. Estimation of cost savings in act 515 may be performed by estimating an amount of money that would have been saved had one or more sensor readings obtained from the facility exhibited more cost-efficient values than those values observed during the anomalous period identified in act 510.

According to some embodiments, one or more sensor readings received by the consumption management system that correspond to readings obtained during the anomalous period may imply a usage rate of some resource (e.g., electricity) that would have been lower had the sensor reading(s) been equal to nominal values. The estimated cost savings may thereby be equal to the difference between the value of the resources used to produce the sensor reading(s) observed during the anomalous period and the value of the resources that would have been needed to produce the corresponding nominal value(s) instead during the same time period. In some cases, the value of a resource that would have been needed to produce the nominal value(s) during the anomalous time period (hereinafter referred to as the nominal value of the resource) may be determined simply by examining the cost of the resource during that time. For example, if sensor data indicates that a light at the customer facility is switched on during a period of time when it is scheduled to be turned off, and this is detected as an anomaly in act 510, the estimated cost savings may be the cost of electricity expended to keep the light on during this period of time, since turning the light off during this time period would have consumed no electricity.

In other cases, determining what would have happened had the facility been operated differently during the anomalous time period is less straightforward. In particular, a customer facility may be arranged such that the effects of adjusting operational parameters is not analytically determinable as in the above-described example of a light switch, because adjusting an operational parameter may in turn affect how other parts of the facility perform. In the example of a light switch, turning the light on and off may not change how much it costs to operate other aspects of the same facility, as whether the light bulb is on or off may not cause any secondary effects to operation of the facility. In contrast, the effects of adjusting an operational parameter of a heating system having multiple heating zones that heat numerous different rooms is less straightforward, because reducing the heating level in one zone may save money in that the heating system is operated at a lower resource use rate in that zone, but other zones may as a consequence become colder leading to higher resource use rate in those zones.

According to some embodiments, determining cost savings for resources may comprise accessing historical data for a customer facility and producing a predicted resource usage rate during an anomalous period based on the historical data. One technique for determining what would have happened had a facility been operated differently during an anomalous time period is to examine a measure of resource usage obtained by the consumption management system during a comparable earlier time. That is, the effects of adjusting an operational parameter on resource usage may be determined by identifying a comparable time at which the operational parameter was different, and estimating expected savings from the different between that earlier resource usage and the observed resource usage during the anomalous time period. Such an earlier time may be identified in any suitable way, including by accessing data obtained from the facility at a fixed period prior to the anomalous event (e.g., using data from a day earlier, a week earlier, etc.) or by examining data stored by the consumption management system related to usage of the resource that was over-expended during the anomalous event (e.g., a time when the weather was comparable for a heating/cooling resource, thereby providing a comparable time at which heating or cooling needs would be expected to be approximately the same).

According to some embodiments, calculating cost savings in act 515 may comprise examining settings of a device or system at the customer facility to determine a recommended action and associated cost savings. In particular, cost savings that could be produced if a device or system has a particular setting or function available may be different if the device or system does not have that setting or function available. As such, calculating cost savings may comprise examining data stored by the consumption management system that relates to the device or system to identify the greatest cost saving available to the customer.

In some embodiments, calculating cost savings in act 515 may comprise evaluating a life value of a device or system (or other asset) at the customer facility. Evaluating the life value determines how much the asset is currently worth (which may be different from its purchase value due to depreciation, wear, increased chance of failure, current maintenance costs, etc.). The life value may be examined in identifying the highest cost savings available in act 515. For instance, in some use cases, calculating cost savings may comprise determining cost savings when an asset is replaced, determining cost savings when the asset is instead repaired, and identifying which of these two cost savings is greater. A resulting event record can identify the recommendation associated with the greater savings (e.g., a recommendation to replace the asset and the associated savings, when it is determined that the cost of replacement is less than the cost of maintaining or repairing).

In act 520, an event record is generated by the consumption management system. An event record may comprise data summarizing aspects of the anomalous event identified in act 510, the cost savings calculated in act 515 and/or a description of a recommended course of action. The event record may be formatted such that a user interface (e.g., a user interface associated with query interface 180 in the illustrative system 100) may parse the event record and display to a user a summary of the event in a manner that allows the user to identify potential actions to take and cost savings estimated to be associated with those actions, should they be taken by the customer.

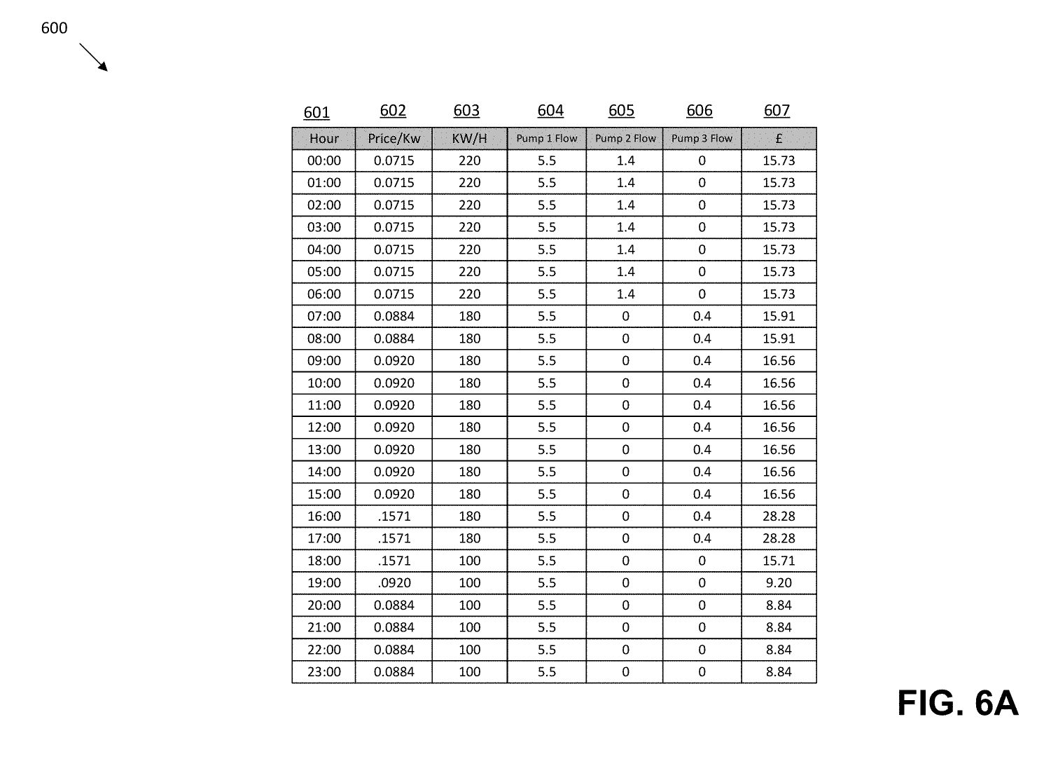

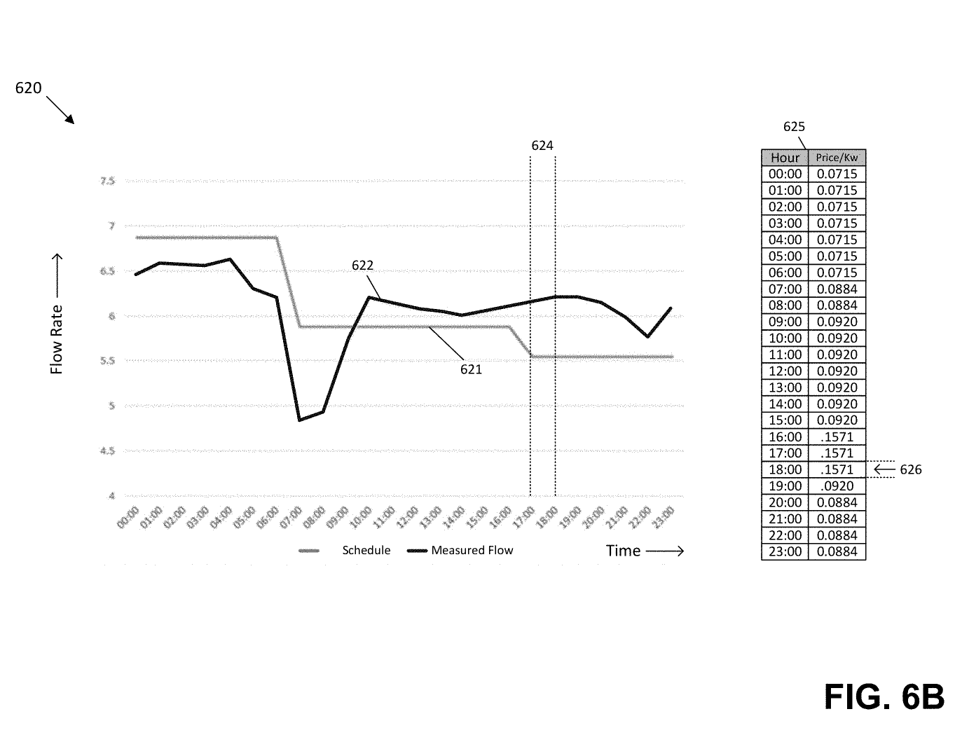

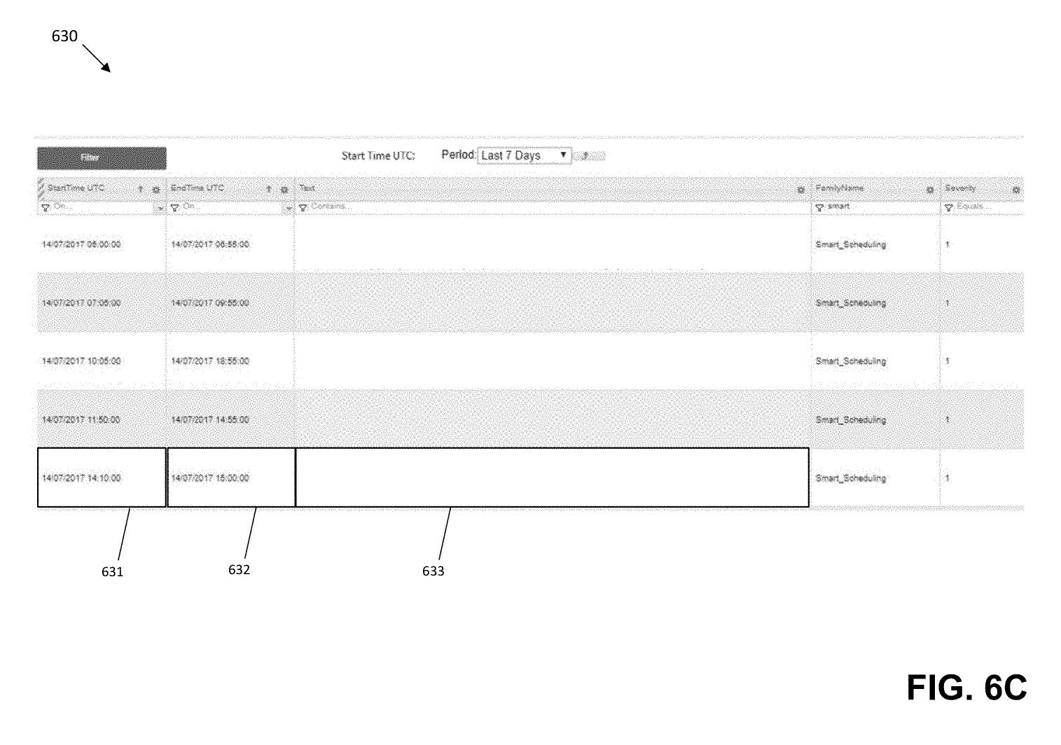

To illustrate some of the techniques discussed above in relation to FIG. 5, FIGS. 6A-6C depict an example of various aspects of a pumping station.

FIG. 6A shows an illustrative schedule for a pumping station, in accordance with some embodiments. In the example of FIG. 6A, a daily schedule for operation of three pumps of a pumping station has been determined. Schedule 600 shows, for each hour of the day (601), the pumping rate of each of the pumps (604, 605, 606), the cost of electricity at various times of the day (602), the total usage at each hour (603) and the total cost for operating during that hour (607). Where a pumping rate is shown as zero in col. 604, 605 or 606, this indicates that the pump is switched off. The schedule 600 may have been determined for a certain set of constraints, such as to meet particular flow demands at certain times of the day, such that the total cost (i.e., the sum of column 607) is minimized for a selected set of values for the pumping rates (cols. 604, 605 and 606) whilst respecting the constraints. Other constraints and/or limitations that may be considered in producing a schedule such as schedule 600 may include reservoir levels in the pumping stations at various times, maximum or minimum flow rates through various portions of the station, applicable tariffs, impacts on water quality, etc.

FIG. 6B shows illustrative flow rate data 620 for the pumping station for which schedule 600 shown in FIG. 6A was developed. The total flow rate is shown on the vertical axis with respect to the scheduled flow rate as per schedule 600 (light gray line 621) and with respect to the flow rate measured by the consumption management system for a given day of operations (black line 622).

In the example of FIG. 6B, one or more anomalies may be identified based on the measured data 622 by identifying times at which the measured flow rate 622 deviates from the scheduled flow rate 621 by more than some threshold amount (e.g., 5%, 10%, etc.). As discussed above, identifying an anomaly based on the measured data may be performed at any time including in real time as the measured data is received by the consumption management system and/or periodically (e.g., at the end of the day, hourly, etc.). In the example of FIG. 6B, an illustrative anomalous time period 624 may be identified during which the measured flow rate increases by more than 10% of its scheduled value. During this one hour period, the measured flow rate varied, but remained sufficiently high compared with the scheduled flow that an anomaly may be generated for this time period.

As discussed above in relation to FIG. 5, cost savings may be calculated and associated with the anomalous time period 624 by considering how much less energy would have been used had the pumps been operated at the scheduled rates. In the example of FIG. 6B, such a calculation may be based on the price of electricity during that time window, shown in table 625 (reproduced from columns 601 and 602 in FIG. 6A) and highlighted at 626. As one illustrative example, cost savings for the anomalous time period 624 may be estimated based on the following formula:

Cost Savings=(Event Duration)×(% Flow Variation)×(Predicted Daily Power)×(Cost per Unit of Power)

The predicted daily power is used in the above example as an estimate of the nominal power usage expected in the absence of an anomalous event. It will be appreciated that the above is only one illustrative formula and other techniques for estimating the cost savings may also be used. For example, as discussed above, the variation in flow during the anomalous time period may be accounted for in the calculation by integrating under the curve 622 to determine the product of (Event Duration) and (% Flow Variation) in a more accurate manner (i.e., to determine ∫ (Event Duration)×(% Flow Variation)).

FIG. 6C shows illustrative event records created for the pumping station comprising resource management recommendations, in accordance with some embodiments. Table 630 illustrates data records generated and stored by the consumption management system in response to the identification of an anomaly and the calculation of expected cost savings associated with addressing the anomaly. Portions of an illustrative record is highlighted through fields 631, 632 and 633. Field 631 identified a start time for the event and field 632 identifies an end time, so that the anomalous time period is delineated by the values of fields 631 and 632. Details associated with the anomalous event are included in field 633 and comprise a description of the anomalous event in addition to values with associated markers that can be parsed by a query engine to display details to a user of the query engine. For example, an illustrative field 633 may include a description of a facility in a manner that can be parsed by a query engine by wrapping the description in a marker or token.

In some embodiments, event records may include data describes a frequency of events of a particular category (e.g., events of the same type, associated with the same asset, generated at the same location, etc.) with time stamps for each instance of the events in this category. Such data may provide a holistic view on a customer facility so that a user can take appropriate actions to remedy commonly occurring issues.

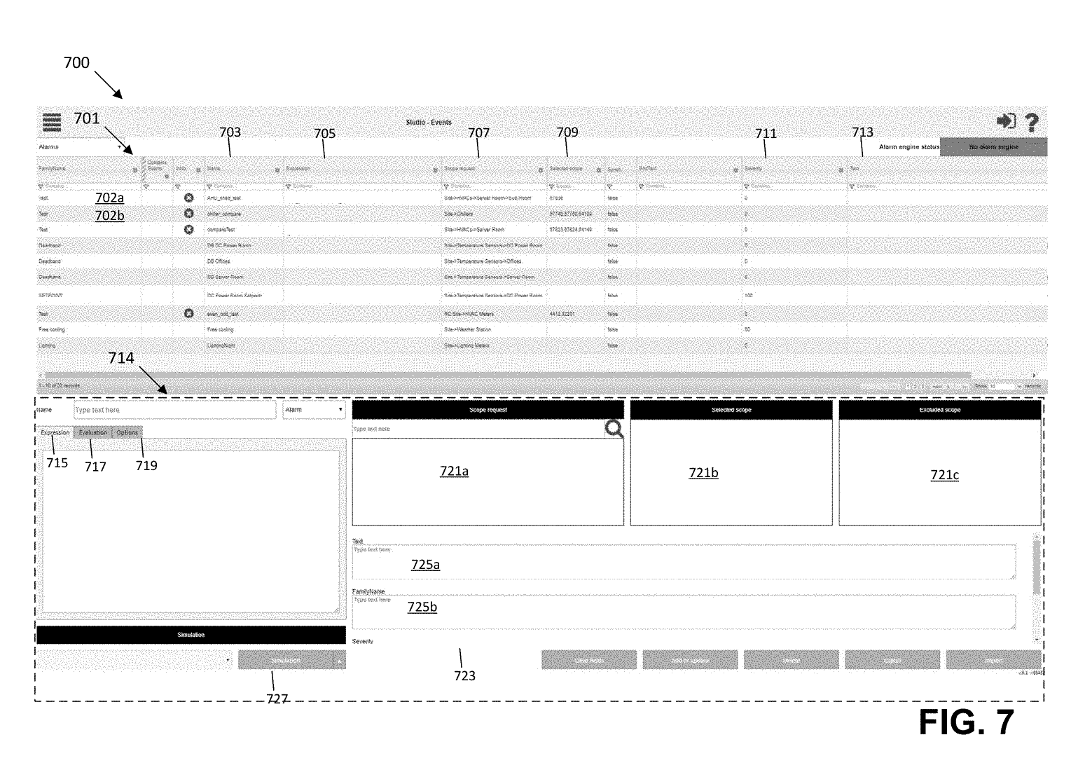

The inventors have recognized that it may be beneficial to provide a user interface for generating an event schedule, e.g. as was discussed with reference to FIG. 5. FIG. 7 depicts an example of a user interface for generating a schedule and/or defining events. For example, the user may provide expected data values, thresholds for deviation, data sources, and other suitable operational parameters to define events in a schedule.

FIG. 7 shows an illustrative event definition page 700, according to some embodiments. The event definition page 700 includes a list of defined events 701 and an event definition area 714, which may be used to create and/or modify the definitions of events based on user input.

Event list 701 displays events in a table and lists characteristics of each event. In the example of FIG. 7, each of rows 702a-b represents events which may have been generated by the user, the consumption management system, or any suitable source. The properties of each event are listed in the columns 703-713. Column 703 lists the name of each event. Column 705 lists an expression associated with the event. Column 707 lists a requested scope associated with the event. Column 709 lists a selected scope associated with each event. Column 711 lists a severity associated with each event. Colum 713 lists a text associated with each event. The event list 701 may include additional columns and event information, such as a family name, options to inhibit or synchronize the event, an end text associated with the event, or any other suitable information. The properties of the events will be discussed with reference to the event definition area 714, which allows the user to create or modify the properties of each event (e.g., the name, expression, scope, and/or text).

Expression tab 715 allows the user to define conditions a data source must satisfy to generate an alarm and/or be considered anomalous. The user may specify the expression using a series of instructions, which may be based on any suitable scripting or programming language or grammar. For example, in some embodiments, the user may specify logical relationships between variables in order to define anomalous events using constraints, such as triggering an anomaly if the data exceeds a user defined threshold. In some embodiments, the user may define an expression that accesses existing variables or instantiates user defined variables, e.g. to be assigned the result of a calculation. In some embodiments, the consumption management system may provide a library of routines, e.g. as part of an application programming interface, to provide functions for the user, for example to access the time of day, date, day of the week, or other suitable data. This allows the user to adjust the event conditions based on context such as the day of the week or operating hours for a facility.

In some embodiments, the expression defined in expression tab 715 operates on a particular object in the object tree of the consumption management system. In some embodiments, the user may access different parts of the object tree by defining an expression that references a broader scope of the event and/or traverses parent and child relationships in the object tree.

Evaluation period 717 allows the user to configure an evaluation period for each event. In some embodiments, the user may specify a length of time for evaluating the event. In some embodiments, the user may specify periods during the day for evaluating the event. In some embodiments, the user may specify weekdays for evaluating the event. In some embodiments, the event can only be triggered during the evaluation period.

Options tab 719 allows the user to control interactions between an events and the consumption management system. For example, the user may opt to inhibit an event thereby preventing the event from being included in the active consumption management system. For example, the user may inhibit an event that is being tested and not ready to be deployed. A user may also stop inhibiting an event once it is ready to be deployed into the consumption management system. In some embodiments, the user may choose to synchronize the data used by an event. In some embodiments, the events may not always have access to the latest consumption management data, for example if the events are inhibited or the user is disconnected from the consumption management system, and may operate using unsynchronized and/or stale data.

Scope request 721a, selected scope 721b, and excluded scope 721c allow the user to specify groups of objects that will be subject to the conditions, e.g. the conditions contained in the expression, of the event. The consumption management system may require that the scope be expressed in any suitable syntax for accessing and/or traversing the object tree. Scope request 721a allows the user to request a type or types of objects to be included in the event. In some embodiments, the user may specify object types directly using a chain of references within the object tree, or any other suitable method of specifying objects. In some embodiments, the scope request generates a list of objects satisfying the request. These objects may be selected or excluded from the final scope. For example, the user may select and/or drag an object into the selected scope 721b to associate the object with the event. The user may select and/or drag an object into the excluded scope 721c to prevent an object from being associated with an event. In some embodiments, the consumption management system selects all of the objects that are requested but not excluded in the absence of user selections.

Event definition page 700 also includes user input area 723 which allows the user to further specify properties of each event. In the example of FIG. 7, the input area 723 includes text boxes 725a and 725b. In some embodiments, input area 723 includes additional text boxes and/or a scroll bar for viewing multiple inputs.

Text box 725a allows the user to associate the event with text that is associated with each detected anomaly. In some embodiments, the text associated with an event may contain dynamic properties that are obtained from a data source or the object tree, e.g. a name or identifier of a specific object within the event scope exhibiting anomalous consumption. In some embodiments, the text of the event is parsed to compute the consumption of a given object and create and/or update an event record with the consumption during the occurrence of the event. In some embodiments, an identifier of an object and the name of a measured property of the object are used to create and/or update an event record. In some embodiments, the consumption management system may require that the text satisfies a particular format, syntax, and/or grammar. For example, the text may be required to include a starting phrase, a description of the event, a consumption threshold for the event, and/or identifiers of associated objects in a particular order. This information may be used to create or update an event record. As a further example, the text may be required to include information used only to create an existing event record such as text to display, an identifier of the corresponding site, a name of a corresponding meter object, an associated state of the event (e.g., any of the states discussed with reference to FIG. 4), a type/category of event record to create, and/or a terminating function that may list device properties. It should be appreciated that these properties are provided by way of illustration only and any property may be used to update and/or create an event record in some embodiments.

Text box 725b allows the user to associate the event with an event family name, which links the event to a specific family of events that share the family name. For example, events related to lighting may be given the family name “lighting.” In some embodiments, this allows the user to organize the events by family name in the event list 701. In some embodiments, the consumption management system may indicate previously created family names for user selection, for example to avoid the entry of unintentionally duplicative or misspelled family names. In some embodiments, the user may be able to create groups of events and/or associate events using any suitable means.

In some embodiments, input area 723 may also include a text box or other input, such as a drop down menu, slider, or numerical radio button, for assigning a severity to each event. In some embodiments, the severity gives the user an indication of how much deviation from expected values the event requires and/or the relative importance of the events. In some embodiments, the severity is specified by a user so that responses to events may be prioritized.

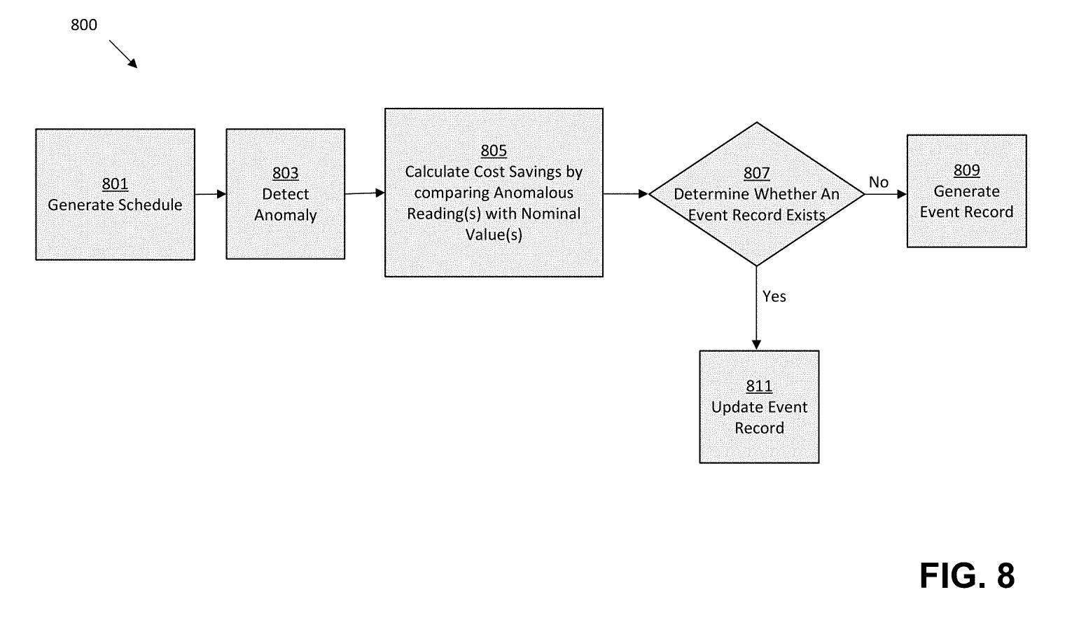

In some embodiments, the input area 723 may also include a text box or other input for assigning an end text to each event. An end text may be used by the consumption management system when the consumption management system terminates an event for reasons other than the end of anomalous consumption. For example, the anomalous consumption may continue for longer than a predetermined time period and the event may be terminated at the end of the time period with the end text being used in place of the text (e.g. that was specified in 725a). In some embodiments, an event may hang or enter an indeterminate state or infinite loop, and the consumption management system may cause the event to time out and terminate. FIG. 8 shows an illustrative process 800 for detecting events and calculating cost savings for a consumption management system, in accordance with some embodiments. As discussed above, a consumption management system may be programmed to compare received data values with predetermined nominal values to detect anomalies in the device(s) and/or system(s) that produce the data values (for example, via event detection module 130 in the example of FIG. 1). Moreover, expected cost savings associated with correction of an anomaly may be calculated based on the received data values and the nominal values. Illustrative process 800 is one example of a process that is configured to perform such an analysis of detecting anomalies and related cost savings.

Illustrative process 800 begins with act 801 in which a schedule is generated. In some embodiments, a schedule may be generated by a consumption management system for a facility wherein the schedule defines, at least in part, a recommended operational approach for the facility. The schedule may define values of one or more operational parameters of the facility at one or more time points over a given period of time (e.g., daily, hourly, weekly, etc.) that are expected, if followed by the facility, to be the most cost efficient manner of operation. As referred to herein, operational parameters of a facility describe various states of devices and/or systems at the facility, such as whether a device is on or off or a configurable setting for a device. A schedule that defines operational parameters over time thereby describes how to operate portions of a facility. In some embodiments, the schedule generated at act 801 may include one or more events that were generated using event definition page 700.

At act 803, an anomaly is detected. As discussed above, an anomaly encompasses any observance of one or more data values that are in some way unexpected given historical or otherwise anticipated values of the relevant data fields. In some cases, a schedule generated in act 801 may provide the anticipated values in that the schedule is defined for a set of operational parameters and detection of an anomaly may comprise determining whether or not the schedule is being followed by the system based on data values obtained from the facility. In some cases, a result of such a comparison may be treated as an anomaly if the observed data value(s) deviate from one or more expected values by greater than some threshold (e.g., more than 10% different, etc.) or may be treated as an anomaly if there is any deviation at all (e.g., if a light is scheduled to be off, but is detected to be on). In some embodiments, a threshold and other constraints on the observed data values may be defined in the expression of an event, which may be defined as was discussed with reference to FIG. 7. Comparisons of data values obtained from the facility with their anticipated values may be performed in real time as the data values are read by the consumption management system and/or periodically based on received data values (e.g., hourly, daily, etc.). In some embodiments, event occurrences have a maximum length, and the consumption management system creates distinct event occurrences after each occurrence of predefined period of anomalous behavior. For example, two continuous hours of anomalous consumption may generate four consecutive event occurrences if each event occurrence is limited to 30 minutes.

In act 805, one or more estimates of cost savings are calculated by comparing obtained data values with their predetermined nominal or threshold values. Such nominal or threshold values may be defined by the consumption management system via a predetermined schedule, event definition page 700, or otherwise. Estimation of cost savings in act 805 may be performed by estimating an amount of money that would have been saved had one or more sensor readings obtained from the facility exhibited more cost-efficient values than those values observed during the anomalous period identified in act 803. In some embodiments, the threshold used to calculate excess resource consumption may be provided to the consumption management system in the text of the event. In some embodiments, the threshold may be different for each occurrence of the event, for example by including a dynamic property used in the text of the event.

In act 807, it is determined whether an event record exists that corresponds to the event. In some embodiments, the consumption management system may determine that an event record corresponds to an event by storing and retrieving an association between the event record and the event and/or determining that event record and the event have the same scope.

If no event record corresponds to the event, for example if such a record never existed, was previously deleted, or otherwise made unsuitable for continued updating, an new event record may be generated for the event in act 809. If a corresponding event record does exist, the event record is updated in act 811 based on the anomalous consumption, the calculated savings, and/or the properties of the event.

In some embodiments, at act 809, the event record is created using parameters included in the text of the event. In some embodiments, the event text provides information for creating the event record, such as an identifier and property of the data source that is used to calculate consumption during the event or any of the properties discussed with reference to the event text and FIG. 7. In some embodiments, the event text includes portions that are used only for creating an event record.

In some embodiments, at act 811, the event record is updated using parameters included in the text of the event. In some embodiments, the event text includes information used to identify the relevant event record as well as properties of the event used to calculate a total resource consumption to be stored in the event record. For example, each event occurrence may include (e.g. in the text of the event) a start time, an end time, and/or the threshold level of consumption for calculating excess consumption. In some embodiments, the threshold is different for each event. In some embodiments, the consumption management system adds the cost savings, excess consumption, and/or other properties of each occurrence of the event to cumulative totals associated with the event in the event record. In some embodiments, the consumption management system may aggregate savings and/or consumption data from any of the event records. In some embodiments, event records may be aggregated based on properties of the underlying events.

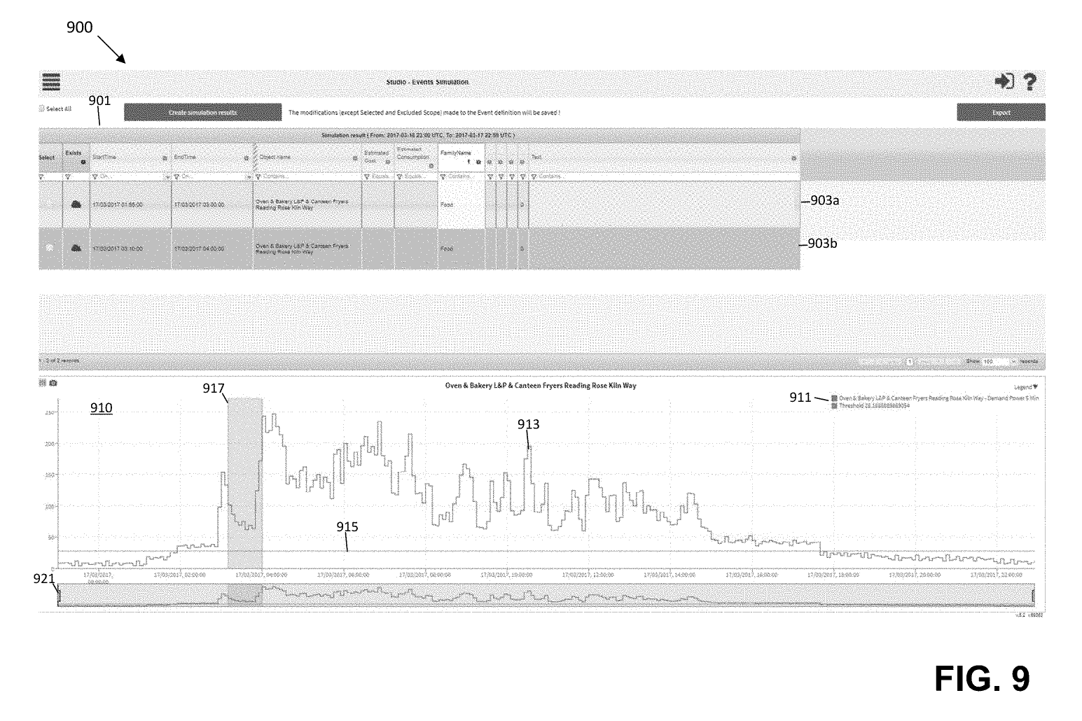

FIG. 9 shows an illustrative event simulation page 900, according to some embodiments. The inventors have recognized that it may be beneficial to provide an interface that may be used to simulate events that are not yet deployed as part of the consumption management system. For example, the user may be able to select an event(s) from a list of events (e.g. 701) and run a simulation of the event(s) (e.g. by selecting 727). In some embodiments, the user may select a time period for the simulation and use data that was recorded by the consumption management system during the selected time period. This allows the user to test, calibrate, and/or debug events using real data without interfering with the operation of the consumption management system.

Simulation page 900 includes an event list 901 that indicates which events 903a-b are being simulated and lists properties of each of the events 903a-b. In some embodiments, the events 903a-b may correspond to separate data sources that are each displayed. In some embodiments, the events 903a-b apply different conditions to the same data source.

Simulation page 900 also includes a simulation display 910. In some embodiments, anomalies that correspond to events selected by the user in the event list 901 are the only anomalies displayed in the simulation display 910. In some embodiments, the simulation display may include multiple data series from different data sources and events that are visually distinguished using any suitable indicia. In the example of FIG. 9, legend 911 identifies the data sources included in the simulation display 910. Line 913 corresponds to a resource consumption profile measured at a site. Threshold line 915 corresponds to a threshold established by one of the events 903a-b. For example, the event may specify that the consumption must be below or within a certain percentage of the threshold during a certain time period (e.g. outside of 6 pm to 2 am). Threshold line 915 allows the user to visually determine how the consumption profile compares to the event threshold throughout the simulated time period. In some embodiments, the user may use slider 921 to adjust the time period displayed in the simulation display 910.

The simulation display 910 may visually indicate where anomalous consumption has occurred. Shaded region 917 indicates that an anomaly has been detected for one of the events 903a-b. The anomaly may be shaded or visually distinguished from the consumption data and other anomalies in any suitable manner. This allows the user to easily, visually ascertain when anomalous consumption occurs. In some embodiments, events may require a monotonic increase, or some other suitable pattern, in consumption as well as additional conditions associated with the consumption. For example, an event may specify that consumption must monotonically increase if consumption begins to increase outside of a certain time range, otherwise the event may indicate that consumption is inefficiently starting and stopping prior to peak hours. It may particularly beneficial to clearly indicate the extent of the anomalous consumption when anomalous consumption cannot be clearly indicated with a threshold.

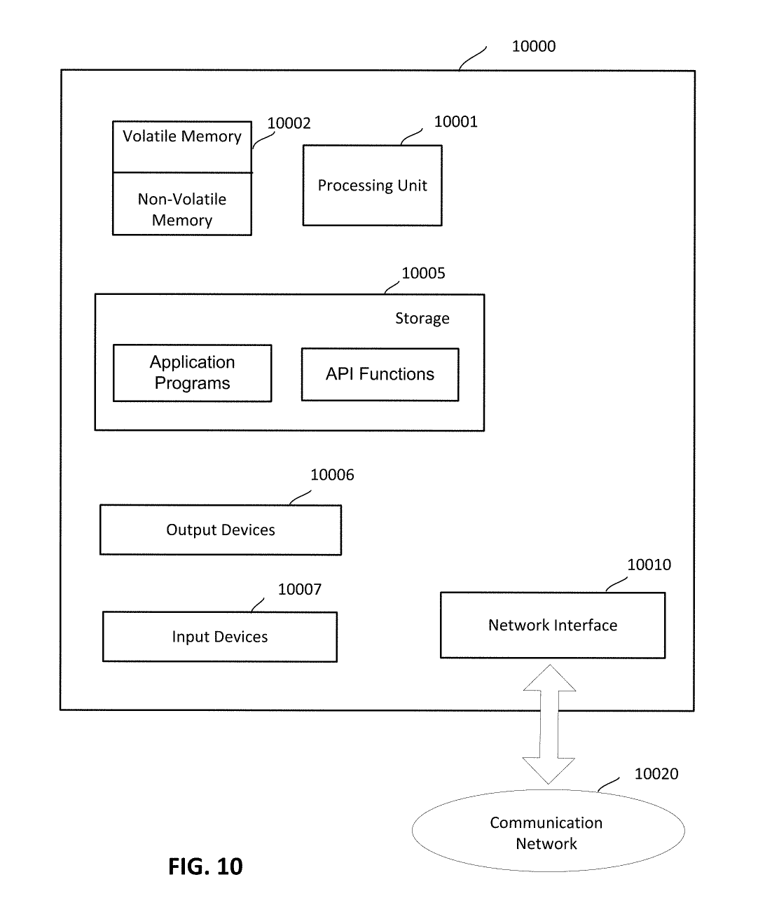

FIG. 10 shows, schematically, an illustrative computer 10000 on which any aspect of the present disclosure may be implemented. In the embodiment shown in FIG. 10, the computer 10000 includes a processing unit 10001 having one or more processors and a non-transitory computer-readable storage medium 10002 that may include, for example, volatile and/or non-volatile memory. The memory 10002 may store one or more instructions to program the processing unit 10001 to perform any of the functions described herein. The computer 10000 may also include other types of non-transitory computer-readable medium, such as storage 10005 (e.g., one or more disk drives) in addition to the system memory 10002. The storage 10005 may also store one or more application programs and/or external components used by application programs (e.g., software libraries), which may be loaded into the memory 10002.

The computer 10000 may have one or more input devices and/or output devices, such as devices 10006 and 10007 illustrated in FIG. 10. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards and pointing devices, such as mice, touch pads, and digitizing tablets. As another example, the input devices 10007 may include a microphone for capturing audio signals, and the output devices 10006 may include a display screen for visually rendering, and/or a speaker for audibly rendering, recognized text.

As shown in FIG. 10, the computer 10000 may also comprise one or more network interfaces (e.g., the network interface 10010) to enable communication via various networks (e.g., the network 10020). Examples of networks include a local area network or a wide area network, such as an enterprise network or the Internet. Such networks may be based on any suitable technology and may operate according to any suitable protocol and may include wireless networks, wired networks or fiber optic networks.

Having thus described several aspects of at least one embodiment, it is to be appreciated that various alterations, modifications, and improvements will readily occur to those skilled in the art. Such alterations, modifications, and improvements are intended to be within the spirit and scope of the present disclosure. Accordingly, the foregoing description and drawings are by way of example only.

The above-described embodiments of the present disclosure can be implemented in any of numerous ways. For example, the embodiments may be implemented using hardware, software or a combination thereof. When implemented in software, the software code can be executed on any suitable processor or collection of processors, whether provided in a single computer or distributed among multiple computers.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the concepts disclosed herein may be embodied as a non-transitory computer-readable medium (or multiple computer-readable media) (e.g., a computer memory, one or more floppy discs, compact discs, optical discs, magnetic tapes, flash memories, circuit configurations in Field Programmable Gate Arrays or other semiconductor devices, or other non-transitory, tangible computer storage medium) encoded with one or more programs that, when executed on one or more computers or other processors, perform methods that implement the various embodiments of the present disclosure discussed above. The computer-readable medium or media can be transportable, such that the program or programs stored thereon can be loaded onto one or more different computers or other processors to implement various aspects of the present disclosure as discussed above.

The terms “program” or “software” are used herein to refer to any type of computer code or set of computer-executable instructions that can be employed to program a computer or other processor to implement various aspects of the present disclosure as discussed above. Additionally, it should be appreciated that according to one aspect of this embodiment, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various features and aspects of the present disclosure may be used alone, in any combination of two or more, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the concepts disclosed herein may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc. in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

In some embodiments, one or more of the following aspects may be provided, in any suitable combination.
1. A consumption management system comprising: at least one storage medium storing a hierarchical data structure, the hierarchical data structure comprising a first level, a second level, and a third level, the third level being lower than the first level and the second level, wherein: the first level comprises a plurality of nodes corresponding, respectively, to a plurality of locations, the plurality of nodes at the first level comprising a first node; the second level comprises a plurality of nodes corresponding, respectively, to a plurality of load categories, the plurality of nodes at the second level comprising a second node that descends from the first node; the third level comprising a plurality of nodes corresponding, respectively, to a plurality of resource consumption meters, the plurality of nodes at the third level comprising a third node that descends from the second node; and a resource consumption meter corresponding to the third node is located at a location corresponding to the first node, and measures resource consumption of one or more pieces of equipment that fall under a load category corresponding to the second node; and at least one processor programmed to access the hierarchical data structure.
2. The consumption management system of aspect 1, wherein: the third node stores at least one property of the resource consumption meter corresponding to the third node, the at least one property comprising a static property, a dynamic property, and/or a derived property.
3. The consumption management system of aspect 1, wherein the at least one processor is programmed to: process data received from at least one data source associated with the resource consumption meter corresponding to the third node, and store a result of processing the data in the third node as a dynamic or derived property.
4. The consumption management system of aspect 1, wherein: the second node stores at least one derived property; and the at least one processor is programed to update the at least one derived property of the second node by performing one or more calculations on data values accessed from one or more nodes of the plurality of nodes at the third level, the one or more nodes descending from the second node.
5. The consumption management system of aspect 4, wherein: the hierarchical data structure comprises a fourth level; the fourth level comprising a plurality of nodes corresponding, respectively, to a plurality of resource consumption sub-meters, the plurality of nodes at the fourth level comprising a plurality of fourth nodes that descend from the third node.
6. The consumption management system of aspect 5, wherein: the one or more nodes of the plurality of nodes at the third level comprises the third node; the accessed data values comprises a value of a derived property of the third node; and the at least one processor is programed to update the derived property of the third node by performing one or more calculations on data values accessed from the plurality of fourth nodes.
7. A method performed by the system of any of aspects 1-6.
8. At least one computer-readable storage medium storing executable instructions that, when executed, cause at least one processor to perform the method of aspect 7.
9. A computer-implemented method of managing resource consumption, comprising: receiving from a facility, by one or more servers, data produced by one or more sensors installed at the facility; detecting, by the one or more servers, an anomaly by comparing the received data with one or more data values describing expected values for the received data and identifying a deviation of the received data from the expected values; and in response to detecting the anomaly, calculating, by the one or more servers, an expected cost savings associated with correction of the anomaly, said calculation comprising: determining a usage price of at least one resource associated with the anomaly; determining, based on the received data, an amount of the at least one resource utilized by the facility as a result of the anomaly; and determining the expected cost savings based on the usage price and the amount of the at least one resource utilized by the facility as a result of the anomaly.
10. The method of aspect 9, further comprising presenting the determined cost savings to a user via at least one user interface.
11. The method of aspect 9, wherein detecting the anomaly comprises identifying that the received data deviates from the expected values by greater than a predetermined threshold.
12. The method of aspect 9, wherein detecting the anomaly comprises identifying a time period during which the received data deviates from the expected values.
13. The method of aspect 12, wherein calculating the expected cost savings associated with correction of the anomaly comprises determining a plurality of usage prices for a plurality of times within the identified time period.
14. The method of aspect 12, wherein calculating the expected cost savings associated with correction of the anomaly comprises determining amounts of the at least one resource utilized by the facility as a result of anomaly for a plurality of times within the identified time period.
15. The method of aspect 9, wherein determining the expected cost savings based on the usage price and the amount of the at least one resource utilized by the facility as a result of the anomaly comprises determining an amount of the at least one resource that would have been utilized by the facility in the absence of the anomaly.
16. The method of aspect 15, wherein determining an amount of the at least one resource that would have been utilized by the facility in the absence of the anomaly comprises accessing historical data, by the one or more servers, describing utilization of the at least one resource at a time prior to the received data being produced by the one or more sensors installed at the facility.
17. The method of aspect 9, wherein the at least one resource includes electricity.
18. A system comprising at least one processor and at least one computer-readable storage medium storing executable instructions that, when executed, cause the at least one processor to perform the method of any of aspects 9-17.
19. At least one computer-readable storage medium storing executable instructions that, when executed, cause at least one processor to perform the method of any of aspects 9-17.
20. A computer-implemented method of managing resource consumption, comprising: receiving from a facility, by one or more servers, data produced by one or more sensors installed at the facility; detecting, by the one or more servers, an anomaly by comparing the received data with one or more data values describing expected values for the received data and identifying a deviation of the received data from the expected values; in response to detecting the anomaly, generating, by the one or more servers, an event record associated with the anomaly, the event record comprising an expected cost savings associated with correction of the anomaly and at least one proposed measure expected to correct the anomaly; presenting at least a portion of the event record to a user via at least one user interface; receiving user input via the at least one user interface indicating that one or more of the at least one proposed measures have been implemented; and updating the event record to indicate said implementation of the one or more of the at least one proposed measures.
21. The method of aspect 20, further comprising calculating, by the one or more servers, the expected cost savings associated with correction of the anomaly.
22. The method of aspect 21, wherein calculating the expected cost savings comprises: determining a usage price of at least one resource associated with the anomaly; determining, based on the received data, an amount of the at least one resource utilized by the facility as a result of the anomaly; and determining the expected cost savings based on the usage price and the amount of the at least one resource utilized by the facility as a result of the anomaly.
23. The method of aspect 22, wherein determining the expected cost savings based on the usage price and the amount of the at least one resource utilized by the facility as a result of the anomaly comprises determining an amount of the at least one resource that would have been utilized by the facility in the absence of the anomaly.
24. The method of aspect 22, wherein determining an amount of the at least one resource that would have been utilized by the facility in the absence of the anomaly comprises accessing historical data, by the one or more servers, describing utilization of the at least one resource at a time prior to the received data being produced by the one or more sensors installed at the facility.
25. The method of aspect 20, wherein detecting the anomaly comprises identifying that the received data deviates from the expected values by greater than a predetermined threshold.
26. The method of aspect 20, wherein detecting the anomaly comprises identifying a time period during which the received data deviates from the expected values.
27. A system comprising at least one processor and at least one computer-readable storage medium storing executable instructions that, when executed, cause the at least one processor to perform the method of any of aspects 20-26.
28. At least one computer-readable storage medium storing executable instructions that, when executed, cause at least one processor to perform the method of any of aspects 20-26.

What is claimed is:

1. A computer-implemented method of managing resource consumption, comprising:
receiving from a facility, by one or more servers, data produced by one or more sensors installed at the facility;
detecting, by the one or more servers, an anomaly by comparing the received data with one or more data values describing expected values for the received data and identifying a deviation of the received data from the expected values;
in response to detecting the anomaly, generating, by the one or more servers, an event record associated with the anomaly, the event record comprising an expected cost savings associated with correction of the anomaly and at least one proposed measure expected to correct the anomaly;
presenting at least a portion of the event record to a user via at least one user interface;
receiving user input via the at least one user interface indicating that one or more of the at least one proposed measures have been implemented; and
updating the event record to indicate said implementation of the one or more of the at least one proposed measures.

2. The method of claim 1, further comprising calculating, by the one or more servers, the expected cost savings associated with correction of the anomaly.

3. The method of claim 2, wherein calculating the expected cost savings comprises:
determining a usage price of at least one resource associated with the anomaly;
determining, based on the received data, an amount of the at least one resource utilized by the facility as a result of the anomaly; and
determining the expected cost savings based on the usage price and the amount of the at least one resource utilized by the facility as a result of the anomaly.

4. The method of claim 3, wherein determining the expected cost savings based on the usage price and the amount of the at least one resource utilized by the facility as a result of the anomaly comprises determining an amount of the at least one resource that would have been utilized by the facility in the absence of the anomaly.

5. The method of claim 3, wherein determining an amount of the at least one resource that would have been utilized by the facility in the absence of the anomaly comprises accessing historical data, by the one or more servers, describing utilization of the at least one resource at a time prior to the received data being produced by the one or more sensors installed at the facility.

6. The method of claim 1, wherein detecting the anomaly comprises identifying that the received data deviates from the expected values by greater than a predetermined threshold.

7. The method of claim 1, wherein detecting the anomaly comprises identifying a time period during which the received data deviates from the expected values.

8. A consumption management system comprising:
at least one processor; and
at least one storage medium storing executable instructions that, when executed, cause the at least one processor on one or more servers to perform a method comprising:
receiving from a facility, by the one or more servers, data produced by one or more sensors installed at the facility;
detecting, by the one or more servers, an anomaly by comparing the received data with one or more data values describing expected values for the received data and identifying a deviation of the received data from the expected values;
in response to detecting the anomaly, generating, by the one or more servers, an event record associated with the anomaly, the event record comprising an expected cost savings associated with correction of the anomaly and at least one proposed measure expected to correct the anomaly;
presenting at least a portion of the event record to a user via at least one user interface;
receiving user input via the at least one user interface indicating that one or more of the at least one proposed measures have been implemented; and
updating the event record to indicate said implementation of the one or more of the at least one proposed measures.

9. The system of claim 8, wherein the method further comprises:
calculating, by the one or more servers, the expected cost savings associated with correction of the anomaly.

10. The system of claim 9, wherein calculating the expected cost savings comprises:
determining a usage price of at least one resource associated with the anomaly;
determining, based on the received data, an amount of the at least one resource utilized by the facility as a result of the anomaly; and
determining the expected cost savings based on the usage price and the amount of the at least one resource utilized by the facility as a result of the anomaly.

11. The system of claim 10, wherein determining the expected cost savings based on the usage price and the amount of the at least one resource utilized by the facility as a result of the anomaly comprises:
determining an amount of the at least one resource that would have been utilized by the facility in the absence of the anomaly.

12. The system of claim 10, wherein determining an amount of the at least one resource that would have been utilized by the facility in the absence of the anomaly comprises:
accessing historical data, by the one or more servers, describing utilization of the at least one resource at a time prior to the received data being produced by the one or more sensors installed at the facility.

13. The system of claim 8, wherein detecting the anomaly comprises:
identifying that the received data deviates from the expected values by greater than a predetermined threshold.

14. The system of claim 8, wherein detecting the anomaly comprises:
identifying a time period during which the received data deviates from the expected values.

15. At least one computer-readable storage medium storing executable instructions that, when executed, cause at least one processor in one or more servers to perform a consumption management method, comprising:
receiving from a facility, by the one or more servers, data produced by one or more sensors installed at the facility;
detecting, by the one or more servers, an anomaly by comparing the received data with one or more data values describing expected values for the received data and identifying a deviation of the received data from the expected values;
in response to detecting the anomaly, generating, by the one or more servers, an event record associated with the anomaly, the event record comprising an expected cost savings associated with correction of the anomaly and at least one proposed measure expected to correct the anomaly;
presenting at least a portion of the event record to a user via at least one user interface;
receiving user input via the at least one user interface indicating that one or more of the at least one proposed measures have been implemented; and
updating the event record to indicate said implementation of the one or more of the at least one proposed measures.

16. The one computer-readable storage medium of claim 15, wherein the method further comprises:
calculating, by the one or more servers, the expected cost savings associated with correction of the anomaly.

17. The one computer-readable storage medium of claim 16, wherein calculating the expected cost savings comprises:
determining a usage price of at least one resource associated with the anomaly;
determining, based on the received data, an amount of the at least one resource utilized by the facility as a result of the anomaly; and
determining the expected cost savings based on the usage price and the amount of the at least one resource utilized by the facility as a result of the anomaly.

18. The one computer-readable storage medium of claim 17, wherein determining the expected cost savings based on the usage price and the amount of the at least one resource utilized by the facility as a result of the anomaly comprises:
determining an amount of the at least one resource that would have been utilized by the facility in the absence of the anomaly.

19. The one computer-readable storage medium of claim 17, wherein determining an amount of the at least one resource that would have been utilized by the facility in the absence of the anomaly comprises:
accessing historical data, by the one or more servers, describing utilization of the at least one resource at a time prior to the received data being produced by the one or more sensors installed at the facility.

20. The one computer-readable storage medium of claim 15, wherein detecting the anomaly comprises:
identifying that the received data deviates from the expected values by greater than a predetermined threshold.

21. The one computer-readable storage medium of claim 15, wherein detecting the anomaly comprises:
identifying a time period during which the received data deviates from the expected values.
